(19) United States
(12) Patent Application Publication
(10) Pub. No.: US 2026/0340560 A1
(43) Pub. Date: Oct. 29, 2026

(54) SYSTEM

(71) Applicant: SoftBank Group Corp., Tokyo (JP)

(72) Inventor: Tetsu SHIBUTANI, Tokyo (JP)

(73) Assignee: SoftBank Group Corp., Tokyo (JP)

(21) Appl. No.: 19/649,215

(22) Filed: Apr. 16, 2026

(30) Foreign Application Priority Data
Apr. 23, 2025 (JP) 2025-071687

(51) Int. Cl. G06Q 10/0637; G06F 9/455; G06F 9/50; G06F 18/21; G06F 30/20; G06F 40/295; G06F 40/30; G06N 3/042; G06N 3/0475; G06N 5/04

(52) U.S. Cl. CPC G06Q 10/06375; G06F 9/455; G06F 9/5016; G06F 9/5072; G06F 18/217; G06F 30/20; G06F 40/295; G06F 40/30; G06N 3/042; G06N 3/0475; G06N 5/04

(57) ABSTRACT

The present invention relates to a system for highly accurately predicting and visualizing reactions, motivation changes, defection risks, and the like of members at the time of organizational reform or policy introduction. A virtual agent having detailed attributes such as age, gender, title, affiliated department, and psychological tendency is generated for each member, and a reaction tendency and an influence relationship of each agent are extracted by analyzing past communication history and unstructured data using generative AI. At the time of inputting a policy proposal, the generative AI simulates the reaction of each agent, and multilaterally visualizes an opinion distribution such as approval, opposition, and defection, and a motivation transition, thereby supporting prompt and accurate strategy planning by a decision maker.

### CROSS-REFERENCE TO RELATED APPLICATION

The present application claims priority to and incorporates by reference the entire contents of Japanese Patent Application No. 2025-071687 filed in Japan on Apr. 23, 2025.

### BACKGROUND OF THE INVENTION

### 1. Field of the Invention

The technology of this disclosure relates to a system.

### 2. Description of the Related Art

Japanese Patent Application Laid-open No. 2022-180282 discloses a persona chatbot control method executed by at least one processor, comprising: receiving a user utterance, adding the user utterance to a prompt containing instructions related to the character of the chatbot, encoding the prompt, inputting the encoded prompt into a language model, and generating a chatbot utterance in response to the user utterance.

The problem to be solved by the present invention is that when managers and management having personnel authority in an organization make important decisions such as organizational reform, personnel allocation, department integration, and policy introduction, they are too afraid of failure to take a step toward a large-scale transformation, and as a result, the speed of reform significantly decreases by repeating small-scale changes, causing adverse effects such as a lack of personnel fluidity in a specific department for a long period of time, which becomes a hotbed of rut and injustice, while conventionally there is no means to specifically and quantitatively grasp the effects and risks of organizational reform, reactions in the field, signs of defection and motivation decline, and the like in advance, and problems become apparent only after the implementation of a policy; furthermore, even in the entire society and external communities, it is difficult to predict in advance how a specific topic or remark, a marketing policy, information transmission at the time of a disaster, and the like spread, flame up, or calm down, and it is not possible to sufficiently grasp a flame-up risk, a trend of public opinion, a route of information propagation, and a range of influence; and in addition, it is not possible to highly accurately model a psychological tendency, an opinion formation pattern, an influence relationship, a motivation fluctuation factor, and the like of individual members and social agents by utilizing a vast amount of communication history, SNS posting data, and the like inside and outside the organization, and to multilaterally and dynamically predict and visualize reactions for each policy or topic.

### SUMMARY OF THE INVENTION

A means for solving the above problem is to provide an agent generation unit configured to model each member in an organization as an agent, assign attribute information such as age, gender, title, affiliated department, motivation value, and past communication history to each agent, and generate and hold the attribute information as agent data; further provide a data analysis unit configured to analyze past dialogue history and opinion expression data acquired from e-mails, communication tools, and the like in the organization, and automatically extract and update attributes and tendencies of each agent; and further provide a simulation execution unit configured to receive a virtual topic or event such as an organizational reform or a policy proposal as an input, simulate what kind of reaction (approval, neutrality, opposition, defection, proposal, etc.) each agent shows to the topic or event using generative AI, and aggregate and visualize the result by department, by attribute, and by individual, wherein the simulation execution unit is configured to be capable of highly accurately and dynamically predicting the reaction of each agent in the organization using natural language processing by the generative AI and inference based on attribute parameters, and multilaterally visualizing an opinion distribution, a motivation change, a defection risk, a necessity of an additional policy, and the like of the entire organization before implementation of a policy.

### BRIEF DESCRIPTION OF THE DRAWINGS

FIG. 1 is a conceptual diagram showing an example configuration of a data processing system according to the first embodiment;

FIG. 2 is a conceptual diagram showing an example of main functions of a data processing device and a smart device according to the first embodiment;

FIG. 3 is a conceptual diagram showing an example configuration of a data processing system according to the second embodiment;

FIG. 4 is a conceptual diagram showing an example of main functions of a data processing device and smart glasses according to the second embodiment;

FIG. 5 is a conceptual diagram showing an example configuration of a data processing system according to the third embodiment;

FIG. 6 is a conceptual diagram showing an example of main functions of a data processing device and a headset-type terminal according to the third embodiment;

FIG. 7 is a conceptual diagram showing an example configuration of a data processing system according to the fourth embodiment;

FIG. 8 is a conceptual diagram showing an example of main functions of a data processing device and a robot according to the fourth embodiment;

FIG. 9 shows an emotion map where multiple emotions are mapped; and

FIG. 10 shows an emotion map where multiple emotions are mapped.

### DETAILED DESCRIPTION OF THE PREFERRED EMBODIMENTS

Hereinafter, an example of an embodiment of the system related to the technology disclosed herein will be described with reference to the attached drawings.

First, the terminology used in the following description will be explained.

In the following embodiments, a processor indicated by reference numeral (hereinafter simply referred to as “processor”) may be a single computing device or a combination of multiple computing devices. The processor may be a single type of computing device or a combination of multiple types of computing devices. Examples of computing devices include a CPU (Central Processing Unit), GPU (Graphics Processing Unit), GPGPU (General-Purpose computing on Graphics Processing Units), APU (Accelerated Processing Unit), among others.

In the following embodiments, a RAM (Random Access Memory) indicated by reference numeral is a memory where information is temporarily stored and used as a work memory by the processor.

In the following embodiments, a storage indicated by reference numeral is one or more non-volatile storage devices for storing various programs and parameters. Examples of non-volatile storage devices include flash memory (SSD (Solid State Drive)), magnetic disks (e.g., hard disks), or magnetic tapes, among others.

In the following embodiments, a communication I/F (Interface) indicated by reference numeral is an interface including a communication processor and an antenna, among others. The communication I/F manages communication between multiple computers. Examples of communication standards applicable to the communication I/F include wireless communication standards such as 5G (5th Generation Mobile Communication System), Wi-Fi (registered trademark), or Bluetooth (registered trademark), among others.

In the following embodiments, “A and/or B” means “at least one of A and B.” In other words, “A and/or B” means it may be only A, only B, or a combination of A and B. Moreover, when expressing three or more items connected by “and/or,” the same concept as “A and/or B” applies.

### First Embodiment

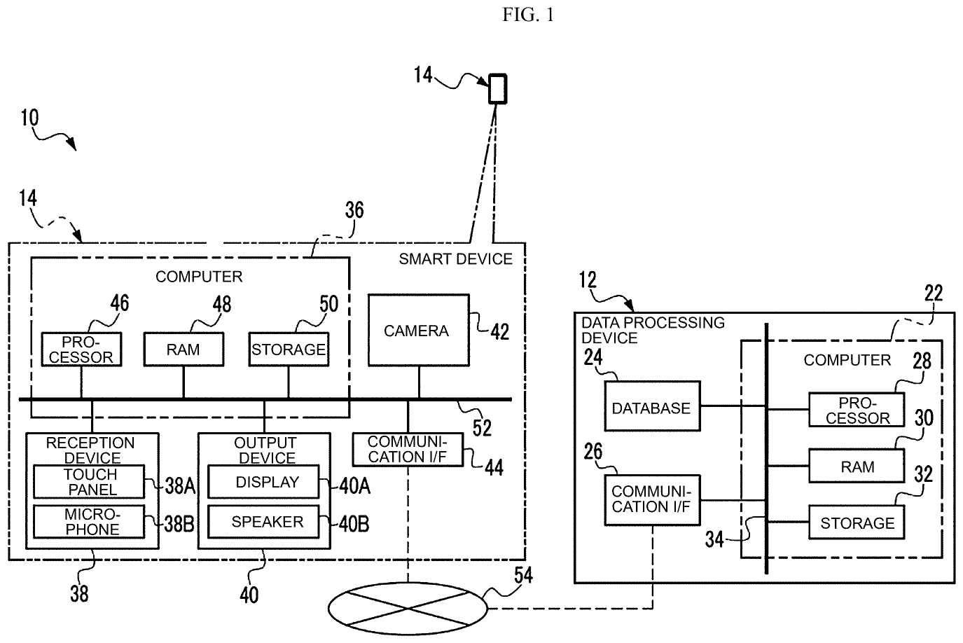

FIG. 1 shows an example configuration of a data processing system 10 according to the first embodiment.

As shown in FIG. 1, the data processing system 10 comprises a data processing device 12 and a smart device 14. An example of the data processing device 12 is a server.

The data processing device 12 comprises a computer 22, a database 24, and a communication I/F 26. The computer 22 is an example of a “computer” related to the technology disclosed herein. The computer 22 comprises a processor 28, RAM 30, and storage 32. The processor 28, RAM 30, and storage 32 are connected to a bus 34. Additionally, the database 24 and communication I/F 26 are also connected to the bus 34. The communication I/F 26 is connected to a network 54. Examples of the network 54 include a WAN (Wide Area Network) and/or a LAN (Local Area Network), among others.

The smart device 14 comprises a computer 36, a reception device 38, an output device 40, a camera 42, and a communication I/F 44. The computer 36 comprises a processor 46, RAM 48, and storage 50. The processor 46, RAM 48, and storage 50 are connected to a bus 52. The reception device 38, output device 40, camera 42, and communication I/F 44 are also connected to the bus 52.

The reception device 38 comprises a touch panel 38A and a microphone 38B, among others, and accepts user input. The touch panel 38A accepts user input by detecting contact from an indicating object (e.g., a pen or finger). The microphone 38B accepts user input by detecting the user's voice. The control unit 46A in the processor 46 sends data indicating user input accepted by the touch panel 38A and microphone 38B to the data processing device 12. In the data processing device 12, the specific processing unit 290 acquires data indicating user input.

The output device 40 comprises a display 40A and a speaker 40B, among others, and presents data to the user 20 by outputting it in a perceptible form (e.g., audio and/or text). The display 40A displays visible information such as text and images according to instructions from the processor 46. The speaker 40B outputs audio according to instructions from the processor 46. The camera 42 is a small digital camera equipped with optical systems such as lenses, apertures, and shutters, as well as imaging elements such as CMOS (Complementary Metal-Oxide-Semiconductor) image sensors or CCD (Charge Coupled Device) image sensors.

The communication I/F 44 is connected to the network 54. The communication I/F 44 and 26 manage the exchange of various information between the processor 46 and the processor 28 via the network 54.

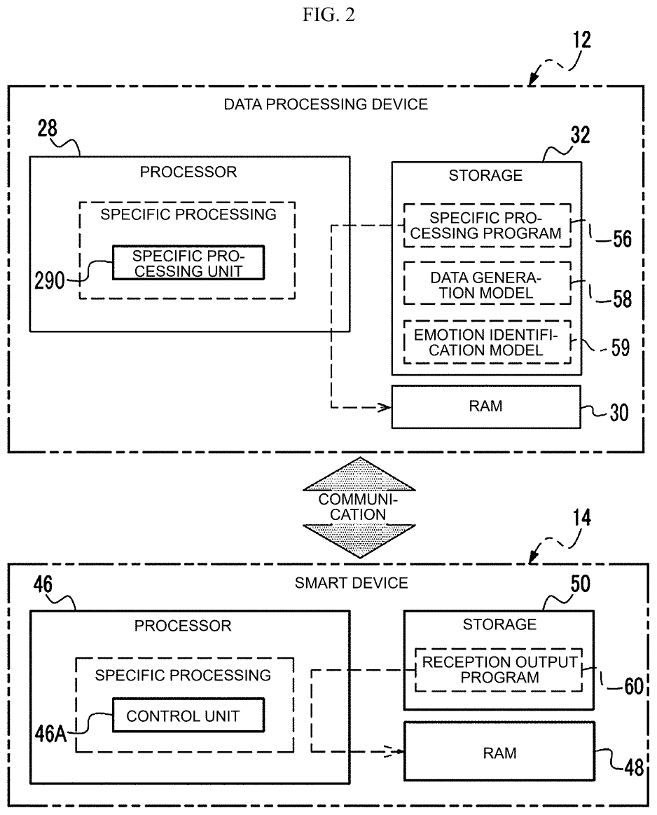

FIG. 2 shows an example of the main functions of the data processing device 12 and the smart device 14.

As shown in FIG. 2, specific processing is performed in the data processing device 12 by the processor 28. The storage 32 stores a specific processing program 56. The specific processing program 56 is an example of a “program” related to the technology disclosed herein. The processor 28 reads the specific processing program 56 from the storage 32 and executes it on the RAM 30. The specific processing is realized by the processor 28 operating as a specific processing unit 290 according to the specific processing program 56 executed on the RAM 30.

The storage 32 stores a data generation model 58 and an emotion identification model 59. The data generation model 58 and emotion identification model 59 are used by the specific processing unit 290. The specific processing unit 290 can estimate the user's emotions using the emotion identification model 59 and perform specific processing using the user's emotions. The emotion estimation function (emotion identification function) using the emotion identification model 59 includes estimating and predicting the user's emotions, and various estimations and predictions related to the user's emotions are performed, but it is not limited to such examples. Furthermore, emotion estimation and prediction may include, for example, emotion analysis.

In the smart device 14, reception output processing is performed by the processor 46. The storage 50 stores a reception output program 60. The reception output program 60 is used in conjunction with the specific processing program 56 by the data processing system 10. The processor 46 reads the reception output program 60 from the storage 50 and executes it on the RAM 48. The reception output processing is realized by the processor 46 operating as a control unit 46A according to the reception output program 60 executed on the RAM 48. The smart device 14 may also have similar data generation models and emotion identification models as the data generation model 58 and emotion identification model 59, and perform the same processing as the specific processing unit 290 using these models. The reception output processing is realized by the processor 46 operating as the control unit 46A according to the reception output program 60 executed on the RAM 48.

Other devices besides the data processing device 12 may have the data generation model 58.

For example, a server device (e.g., a generation server) may have the data generation model 58.

In this case, the data processing device 12 communicates with the server device having the data generation model 58 to obtain processing results (e.g., prediction results) using the data generation model 58. The data processing device 12 may be a server device or a terminal device owned by the user (e.g., a mobile phone, robot, home appliance, etc.). Next, an example of processing by the data processing system 10 according to the first embodiment will be described.

### Example 1

The flow of the specific processing in Example 1 will be described. Each part of the system described below is realized by the data processing device 12 and the smart device 14. Additionally, the data processing device 12 is referred to as a “server,” and the smart device 14 is referred to as a “terminal.”

### Embodiment for Carrying Out the Present Invention

Embodiments of the present invention will be described more specifically and in detail. The system of the present invention is realized by cooperation between a server and a terminal, and an agent generation unit, a data analysis unit, a simulation execution unit, a database unit, and an AI learning management unit are provided on the server side, and a user interface unit, a policy input unit, and a result browsing/analysis unit are provided on the terminal side. Specifically, this system operates in a distributed computing environment. This server includes a parallel computing cluster composed of a plurality of computing nodes. This terminal is an information processing apparatus including a graphics processing unit. This system executes a data compression algorithm to reduce a communication load between the server and the terminal. This agent generation unit maps a virtual agent onto a multidimensional vector space. This data analysis unit converts text data into a tensor representation using a natural language processing model. This simulation execution unit calculates a state transition probability using a Markov chain Monte Carlo method. This database unit is configured by combining a distributed relational database and a graph database. This AI learning management unit updates weight parameters of a neural network using an error backpropagation algorithm. This user interface unit renders a three-dimensional visualization object on a display of the terminal. This policy input unit detects an input operation from a user and executes an interrupt process. This result browsing/analysis unit decodes chronological array data received from the server. Thereby, this system exhibits technical effects of improving calculation efficiency and processing speed in a large-scale organizational simulation. This configuration is useful in specific application fields such as preliminary verification of personnel policies and simulation of organizational restructuring.

First, the agent generation unit operates on the server and automatically acquires all kinds of attribute information such as name, age, gender, title, affiliated department, years of service, past transfer history, evaluation history, commendation/disciplinary history, qualification information, skill set, language ability, place of origin, family structure, commuting time, working style (remote/office attendance), and health checkup results from a personnel management system and a business management system in the organization. For example, it generates an agent having detailed attributes such as a 45-year-old male who is a general manager of department A, has experienced transfers three times in the past, has a high recent evaluation, has taken leadership training, has a family of a spouse and two children, has a commuting time of one hour, and has an item requiring observation in a health checkup. Furthermore, utilizing generative AI, it extracts personality tendencies (e.g., “proactive about new policies”, “conservative”, “risk-averse”, “highly cooperative”, “strongly assertive”, “low stress tolerance”, etc.), values (e.g., “emphasis on work-life balance”, “promotion-oriented”, “stability-oriented”, “challenge-oriented”, etc.), and psychological parameters (e.g., “current satisfaction level”, “future anxiety level”, “trust level in the organization”, etc.) of each agent from unstructured data such as past daily business reports, meeting minutes, internal SNS postings, questionnaire answers, and 1-on-1 interview records, and assigns them as agent attributes. For example, the AI automatically determines that “this employee is positive about a new project based on past remarks” or “this employee tends to show a strong resistance to a transfer” by natural language processing, and reflects it as a reaction tendency parameter of the agent. Specifically, this agent generation unit normalizes the acquired attribute information and converts it into a fixed-length numerical vector. This agent generation unit tokenizes the unstructured data as preprocessing and generates a word embedding vector. This generative AI includes a large language model based on a transformer architecture. Input data to this large language model is a chronological array consisting of a token sequence of up to 512 dimensions. Specific examples of the input data include text data of daily business reports, transcript text of meeting minutes, and posting text of an internal social network. This large language model calculates context dependencies in the text using a self-attention mechanism. Output data from this large language model is a probability distribution vector having continuous values from zero to one corresponding to each personality tendency and psychological parameter. Specific examples of the output data include numerical vectors such as a score indicating proactiveness toward a new policy being 0.85, a score indicating a current satisfaction level being 0.42, and a score indicating a trust level in the organization being 0.71. This agent generation unit inputs this output result to a threshold determination process. This agent generation unit activates a specific reaction tendency flag when the score exceeds a predetermined threshold. This agent generation unit combines these numerical vectors and flags to construct an initial state tensor of each agent. Unlike conventional profiling that relies on human subjective evaluation, this processing method realizes objective and highly reproducible feature extraction based on vector operations in a high-dimensional space. Thereby, this system exhibits technical effects of improving the accuracy of the agent model and improving data management. This configuration is useful in specific application fields such as mental health prediction of employees and automatic proposal of optimal placement.

The data analysis unit operates on the server and collects and integrates all kinds of communication history such as e-mails, chats, SNS, business reports, meeting minutes, questionnaire results, employee satisfaction surveys, exit interview records, and internal event participation history in the organization. The generative AI performs natural language analysis on these massive amounts of text data, and automatically extracts opinion tendencies and emotional tendencies by department and by individual, such as “employees in department A have many negative opinions about integration with department B”, “employees in department C are proactive about a new project”, and “young employees in department B feel strong anxiety about a change in the evaluation system”. Furthermore, the AI uses time-series analysis and sentiment analysis to identify a group of employees whose motivation has increased after the announcement of a specific policy, or conversely, a group of employees who have shown a defection tendency. For example, from e-mail exchanges when department integration was implemented in the past, the AI automatically learns patterns such as “the intention to resign among young employees in department B increased immediately after the integration” and “managers in department A actively participated in the new system after the integration”, and reflects them in future simulations. Furthermore, the AI automatically extracts an influence relationship network in the organization (e.g., “the general manager of department A has a strong influence on the section manager of department B”, “the leader of department C has a great influence on the opinion formation pattern of young employees”, etc.) and records it as an influence degree parameter between agents. Specifically, this data analysis unit executes a data cleansing process to remove noise from the collected communication history. This data analysis unit performs morphological analysis on the text data and performs part-of-speech tagging. This generative AI includes a sentiment analysis model combining a recurrent neural network and a long short-term memory unit. Input data to this sentiment analysis model is a time-series tensor of word embedding vectors to which time information is added. Specific examples of the input data include vector representations of e-mail bodies before and after the announcement of a specific policy, chronological arrays of remarks in a chat tool, and embedding vectors of free-text answers to questionnaires. This sentiment analysis model executes a convolution operation and a pooling operation on the input tensor. Output data from this sentiment analysis model is an output vector of a softmax function indicating classification probabilities for positive, negative, and neutral emotion classes. Specific examples of the output data include numerical data such as a negative probability for an integration policy being 0.8, a positive probability for a new project being 0.9, and an anxiety score for an evaluation system change being 0.75. This data analysis unit inputs this output result to a graph neural network. This graph neural network constructs an adjacency matrix with agents as nodes and communication frequencies as edge weights. This graph neural network executes a message passing algorithm to calculate an influence degree score between nodes. Unlike a conventional method based on a simple keyword search, this processing method is an unconventional procedure combining deep learning of context and analysis of a graph structure. Thereby, this system exhibits technical effects of improving the visualization accuracy of potential human relations in the organization and reducing the prediction error of emotional changes. This configuration is useful in specific application fields such as quantitative evaluation of organizational culture and identification of influencers.

The simulation execution unit mainly operates on the server, and can also be provided with some interactive simulation display and parameter adjustment functions on the terminal side. A user (manager or management layer) inputs a virtual policy proposal or topic (e.g., “integration of department A and department B”, “launch of a new project”, “change in an evaluation system”, “large-scale personnel transfer”, “introduction of a new welfare system”, “expansion of a remote work ratio”, “opening of a new base”, “change of top management”, “launch of a new product”, “response to the occurrence of a scandal”, etc.) from the terminal. The server predicts what kind of reaction each agent shows to the policy or topic using the generative AI. The AI comprehensively considers the attribute parameters of the agent, past reaction tendencies, the influence relationship network in the organization, sentiment analysis results of the policy content, data at the time of similar policies in the past, and the like, and probabilistically calculates reactions such as “approval”, “neutrality”, “opposition”, “defection”, “new proposal”, “silence”, “passive approval”, and “active opposition”. For example, the AI automatically generates various reactions such as “the general manager of department A approves of the integration, young employees in department B strongly oppose it, and some employees in department C make a new proposal that ‘our own department should also be subject to the integration’” and “managers approve of the evaluation system change, but field employees feel anxious and remain passively approving”. In addition, the AI simultaneously predicts the intensity of the reaction and the motivation change, and also outputs numerical simulation results such as “the motivation of department B decreases by an average of 20 points due to the integration policy”, “the leader layer of department A actively participates in the new system after the integration”, and “the defection risk of young employees in department C decreases due to the launch of the new project”. Specifically, this simulation execution unit converts the input policy proposal into a feature vector using a natural language processing model. This simulation execution unit combines this feature vector and the initial state tensor of each agent to generate a simulation input tensor. This generative AI includes an inference engine that executes a multi-agent reinforcement learning algorithm. Input data to this inference engine is a multidimensional tensor including state vectors of all agents, an adjacency matrix indicating influence relationships, and a policy feature vector. Specific examples of the input data include a vector representation of a department integration policy, a state vector of the general manager of department A, and an average state vector of a group of young employees in department B. This inference engine calculates interactions between agents using an attention mechanism. Output data from this inference engine is a probability distribution vector for a reaction category of each agent, and a continuous value score indicating a motivation change amount. Specific examples of the output data include a vector indicating an approval probability of 0.6 and a motivation change amount of plus 5 points, a vector indicating an opposition probability of 0.8 and a motivation change amount of minus 15 points, and a score indicating a defection probability of 0.3. This simulation execution unit inputs this output result to a state update module. This state update module recalculates the state tensor of each agent based on the output result, and executes a simulation of the next time step. Unlike static rule-based branching processing, this processing method is an unconventional processing method that continuously calculates dynamic interactions in a high-dimensional space. Thereby, this system exhibits technical effects of improving the prediction accuracy of complex organizational dynamics and efficiently using calculation resources. This configuration is useful in specific application fields such as stress testing of management strategies and preliminary evaluation of change management.

Furthermore, the AI can summarize the simulation results and present specific suggestions contributing to decision-making, such as “when the integration policy is implemented, the approval rate of department A is 80%, the opposition rate of department B is 60%, and an additional integration proposal is expected to be proposed from department C”, “due to the evaluation system change, the overall motivation temporarily decreases, but tends to recover after half a year”, and “due to the opening of the new base, the satisfaction level of employees living in rural areas significantly improves”. Specifically, this generative AI includes a decoder network specialized for a natural language generation task. Input data to this decoder network is a chronological tensor of reaction probability distribution vectors and motivation change amounts of all agents output from the simulation execution unit. Specific examples of the input data include transition data of approval rates by department for each time step, chronological arrays of motivation average values by title, and aggregated vectors of defection risk scores of specific attribute groups. This decoder network applies a beam search algorithm to the input tensor to search for an optimal word sequence. Output data from this decoder network is structured text data and metadata to which an importance score is assigned. Specific examples of the output data include summary text including a numerical value of an approval rate of 80 percent, prediction text indicating a period until motivation recovery, and highlight text indicating an improvement in satisfaction level. This system inputs this output result to a display control module of the user interface unit. This display control module generates a rendering instruction for highlighting text whose importance score exceeds a predetermined threshold. Unlike a mere enumeration of numerical data, this processing method is an improvement in computer technology that automatically generates a semantic summary understandable by humans from high-dimensional simulation results using a deep learning model. Thereby, this system exhibits technical effects of reducing an information processing load in a decision-making process and speeding up data interpretation. This configuration is useful in specific application fields such as automatic report generation in management meetings and dashboard display of policies.

The user interface unit operates on the terminal and visualizes the simulation results received from the server from various perspectives such as by department, by attribute, by individual, in chronological order, and by network. For example, it can display “which department approves or opposes” color-coded in a heat map, display “motivation change” in chronological order in a bar graph, visualize “opinion propagation among employees having a strong influence relationship” in a network diagram, and show “reaction transition after policy implementation” in a timeline display. Furthermore, it is also possible to adjust parameters of the policy proposal (e.g., “selection of departments subject to integration”, “details of the evaluation system”, “setting of the number of transferred persons”, “scale of the new project”, “welfare content”, etc.) from the terminal and re-execute the simulation in real time. For example, various scenarios such as “when the integration targets are changed to department A and department C”, “when evaluation items of the evaluation system are added”, and “when the opening location of the new base is changed” can be immediately compared and examined. Specifically, this user interface unit executes drawing processing by hardware acceleration using the graphics processing unit of the terminal. This user interface unit converts the multidimensional tensor data received from the server into a two-dimensional or three-dimensional pixel array. This user interface unit executes a heat map generation algorithm and maps continuous values of the approval probability and the opposition probability to a color gradation. This user interface unit executes a graph drawing algorithm based on a dynamic model, converts the influence degree score between nodes into the length and thickness of an edge, and renders a network diagram. This terminal executes an input monitoring thread that detects a parameter change input from the user. This terminal encapsulates the changed parameters into a payload and transmits it to the server via a secure communication protocol. This server analyzes the received payload and dynamically rewrites the initial condition tensor of the simulation execution unit. This server speeds up recalculation processing by utilizing an in-memory database. Unlike a conventional web application based on static screen transitions, this processing method is an advanced interaction technology using asynchronous communication and differential rendering between a client and a server. Thereby, this system exhibits technical effects of minimizing user operation delay and realizing real-time scenario analysis. This configuration is useful in specific application fields such as an interactive management simulator and a real-time risk evaluation tool.

The database unit operates on the server and centrally manages agent data, communication history, simulation history, policy proposal history, AI learning data, and the like. For example, by accumulating past simulation results and continuously learning by the AI, the simulation accuracy can be improved. The AI learning management unit is responsible for managing an AI learning data set, creating training data, constructing a feedback loop, managing versions of an AI model, and the like, and feeds back actual data such as “actual turnover rate after implementation of past policies”, “actual motivation transition”, and “actual opinion distribution” to the AI to continuously improve the prediction accuracy of the AI. Specifically, this database unit includes a column-oriented database engine constructed on a distributed file system. This database unit executes data sharding and replication processing to read and write petabyte-class data at high speed. This AI learning management unit includes a loss function evaluation module that calculates an error between the accumulated simulation history and the actual data. Input data to this AI learning management unit is a correct label tensor consisting of a past prediction tensor and an actual observation value. Specific examples of the input data include a predicted defection probability vector, a binary vector indicating an actual defector, and a chronological array of actual motivation scores. This AI learning management unit calculates a loss value using a cross-entropy error function and a mean squared error function. Output data from this AI learning management unit is a gradient vector indicating a weight update amount in each layer of the neural network. Specific examples of the output data include an update matrix of attention weights of a transformer model, a bias update value of a fully connected layer, and a fine adjustment amount of an embedding vector. This AI learning management unit inputs this output result to a stochastic gradient descent optimizer and asynchronously updates model parameters. Unlike manual parameter adjustment by a human, this processing method is a self-optimization process using automatic error backpropagation based on actual data. Thereby, this system exhibits technical effects of improving generalization performance of the model and preventing aging degradation. This configuration is useful in specific application fields such as automatic deployment of a machine learning model in a continuous integration environment and an adaptive prediction system.

The utilization of the generative AI is the core of the present invention, and the AI is essential in all processes such as agent attribute extraction, communication history analysis, reaction prediction, simulation result generation, summary/visualization data generation, automatic policy proposal generation, and continuous learning of the AI model. For example, the AI extracts opinion tendencies of employees from past e-mails and chats by natural language processing, the AI generates a reaction using attribute parameters and policy content as inputs, the AI converts simulation results into summary/visualization data, and the AI can also automatically generate new policy proposals and organizational structure proposals. For example, the AI can also present specific policy proposals such as “in order to reduce the defection risk of department B, the planning department of department B should be placed directly under the new general manager at the same time as the integration to raise the rank in the organization” and “by selecting a young employee of department C as a leader of a new project, an improvement in motivation can be expected”. Specifically, this generative AI includes an ensemble learning architecture integrating a plurality of specialized neural network models. This generative AI utilizes a generative adversarial network to execute an automatic policy proposal generation task. Input data to this generative adversarial network is a current organizational state tensor, a target motivation score, and a penalty vector indicating a constraint condition. Specific examples of the input data include a current defection risk score array of department B, a target engagement index of the entire organization, and a scalar value indicating a budget constraint. A generator of this generative adversarial network samples random noise from a latent space and generates a candidate vector of a policy proposal. A discriminator of this generative adversarial network compares the generated candidate vector with a past successful policy vector and outputs an authenticity determination score. Output data from this generative AI is a text representation of an optimized policy proposal and a predicted value of an expected effect index. Specific examples of the output data include structured text indicating a procedure for changing an organizational structure, selection proposal data including an identifier of a specific young employee, and a predicted motivation improvement score after execution of the policy. This system inputs this output result to a policy evaluation module, calculates a feasibility score, and transmits it to the user interface unit. Unlike conventional brainstorming relying on human intuition, this processing method is an unconventional procedure in which a computer autonomously solves a high-dimensional constrained optimization problem. Thereby, this system exhibits technical effects of improving processing speed by automating policy planning and improving proposal accuracy based on objective grounds. This configuration is useful in specific application fields such as automation of personnel consulting and algorithm generation of management strategies.

In addition, the system of the present invention is not limited to simulations in an organization, but can also generate a large number of external SNS users and the entire society as virtual agents, and simulate how social topics and remarks, marketing policies, information transmission at the time of a disaster, and the like spread, flame up, and calm down. For example, it generates agents on a scale of 100 million people, assigns age, gender, place of residence, occupation, health condition, past posting tendency, number of followers, influence score, interests, purchase history, evacuation tendency at the time of a disaster, and the like as attributes, and the generative AI predicts and visualizes “how a specific remark spreads on SNS, in which attribute layer a flaming occurs, and at what timing it calms down” in chronological order. For example, it can also be applied to prediction of social impacts such as “how specific information propagates in which region and where misinformation spreads at the time of a disaster”, “which attribute layer shows a favorable reaction and in which layer criticism concentrates at the time of a new product announcement”, and “through what route an inappropriate remark of a celebrity flames up and which layer becomes the center of diffusion”. Specifically, this system deploys an agent model on a scale of 100 million people on a memory using a massively parallel distributed processing framework constructed on a cloud computing environment. This system represents attribute information of each agent as a sparse matrix to reduce memory consumption. This generative AI includes a graph convolutional network extending an infectious disease mathematical model to execute an information diffusion simulation. Input data to this graph convolutional network is a huge adjacency matrix with all agents as nodes and follower relationships as edges, and an activation vector of a node serving as an initial transmission source. Specific examples of the input data include a feature vector encoding specific remark content, a tensor indicating an initial state of an influencer, and a numerical array indicating a past diffusion probability of each user. This graph convolutional network iteratively executes a message passing operation that aggregates feature amounts between adjacent nodes. Output data from this graph convolutional network is a chronological tensor of an information reception probability, a diffusion probability, and an emotion polarity score of each node at each time step. Specific examples of the output data include data indicating that a misinformation arrival rate in a specific region one hour after transmission is 60 percent, data indicating that a favorability score of women in their twenties for a new product is 0.8, and a predicted value indicating a peak arrival time of a flaming state. This system stores this output result in a time-series database and inputs it to a real-time analysis engine. Unlike conventional market prediction based on a small-scale sampling survey, this processing method is advanced arithmetic processing that reproduces a macro social phenomenon on a computer as an accumulation of interactions of micro agents. Thereby, this system exhibits technical effects of improving prediction accuracy of information propagation in a large-scale network and ensuring computational scalability. This configuration is useful in specific application fields such as optimization of digital marketing and a crisis management system at the time of a disaster.

Furthermore, the AI can automatically propose an attribute layer or region with a high flaming risk, a blocking point of a diffusion route, an optimization proposal for a marketing policy, an improvement proposal for an information transmission route at the time of a disaster, and the like based on the simulation results. For example, the AI presents a specific action plan such as “the flaming risk can be reduced by holding a briefing session in advance for a specific attribute layer” and “accurate information should be diffused through highly influential users at the time of a disaster”. Specifically, this system receives a numerical vector of the simulation result as an input. This inference model outputs a risk score and an optimization proposal as a probability distribution. This processing unit executes subsequent screen display processing using this output result.

As described above, the embodiment of the present invention is configured such that the server side is responsible for agent generation, data analysis, simulation execution, database management, and AI learning management, and the terminal side is responsible for a user interface, policy proposal input, and visualization and operation of simulation results, and by utilizing generative AI in all processes, reactions to various policies and topics inside and outside the organization are highly accurately and dynamically simulated, thereby realizing an extremely practical and highly expandable system that contributes to decision-making support, risk prediction, and strategy planning. Specifically, the server controls the entire system by linking each processing module. The large language model extracts feature amounts from input text data. The system improves simulation accuracy using the extracted feature amounts.

### System Configuration

The system according to the present embodiment includes an agent generation unit, a data analysis unit, a simulation execution unit, a user interface unit, a database unit, and an AI learning management unit. The agent generation unit models each member in the organization as a virtual agent based on a wide variety of attribute information such as name, age, gender, title, affiliated department, years of service, past transfer history, evaluation history, commendation/disciplinary history, qualification information, skill set, language ability, place of origin, family structure, commuting time, working style, and health checkup results acquired from a personnel management system and a business management system in the organization, and generates an agent having detailed attributes such as, for example, a 45-year-old male who is a general manager of department A, has experienced transfers three times in the past, has a high recent evaluation, has taken leadership training, has a family of a spouse and two children, has a commuting time of one hour, and has an item requiring observation in a health checkup. In addition, the agent generation unit utilizes generative AI to extract personality tendencies, values, and psychological parameters of each agent from unstructured data such as past business daily reports, meeting minutes, internal SNS postings, questionnaire answers, and 1-on-1 interview records, and assigns information such as, for example, “positive about new policies”, “conservative”, “risk-averse”, “highly cooperative”, “strongly self-assertive”, “low stress tolerance”, “emphasis on work-life balance”, “promotion-oriented”, “stability-oriented”, “challenge-oriented”, “current satisfaction level”, “future anxiety level”, and “trust level in the organization” as agent attributes. Furthermore, the agent generation unit automatically determines reaction tendency parameters such as, for example, “this employee is positive about a new project from past remarks” and “this employee tends to show a strong sense of resistance to a transfer” by natural language processing by the AI, and reflects them in the agent. Specifically, the agent generation unit inputs employee attribute data as a multidimensional tensor. The neural network outputs a label indicating a personality tendency. The system uses this label for subsequent simulation processing.

The data analysis unit collects and integrates various communication histories such as e-mails, chats, SNS, business reports, meeting minutes, questionnaire results, employee satisfaction surveys, exit interview records, and internal event participation histories in the organization, and performs natural language analysis using generative AI. For example, the AI automatically extracts opinion tendencies and emotional tendencies by department and by individual, such as “many employees in department A have negative opinions about integration with department B”, “employees in department C are positive about a new project”, and “young employees in department B feel strong anxiety about an evaluation system change”. Furthermore, the AI uses time-series analysis and sentiment analysis to identify a group of employees whose motivation has increased after a specific policy announcement, or conversely, a group of employees who have shown a defection tendency, automatically learns patterns such as, for example, “the intention to resign of young employees in department B increased immediately after the integration” and “managers in department A actively participated in a new system after the integration”, and reflects them in future simulations. In addition, the AI extracts an influence relationship network in the organization, and records influence degree parameters such as, for example, “the general manager of department A has a strong influence on the section manager of department B” and “the leader of department C has a great influence on opinion formation of young employees”. Furthermore, the AI estimates stress levels and engagement scores of employees, and also extracts information such as, for example, “the stress level of department B is rising due to a recent increase in workload” and “the engagement of department C improved after the start of the new project”. Specifically, the data analysis unit inputs a text history as a time-series array. The analysis model outputs a sentiment score and an influence degree parameter. The system stores these output values in a database to improve processing efficiency.

The simulation execution unit receives a virtual policy proposal or topic input from the terminal by the user, for example, “integration of department A and department B”, “launch of a new project”, “change in an evaluation system”, “large-scale personnel transfer”, “introduction of a new welfare system”, “expansion of a remote work ratio”, “opening of a new base”, “change of top management”, “launch of a new product”, “response at the time of occurrence of a scandal”, and the like, and predicts what kind of reaction each agent shows to the policy proposal or topic using generative AI. The AI comprehensively considers attribute parameters of the agent, past reaction tendencies, an influence relationship network in the organization, a sentiment analysis result of policy contents, data at the time of similar policies in the past, and the like, and probabilistically calculates reactions such as “approval”, “neutrality”, “opposition”, “defection”, “new proposal”, “silence”, “passive approval”, and “active opposition”. For example, the AI automatically generates various reactions such as “the general manager of department A approves of the integration, young employees of department B strongly oppose it, and some employees of department C make a new proposal that ‘our own department should also be subject to the integration’” and “regarding the evaluation system change, the management layer approves, but frontline employees feel anxiety and remain in passive approval”. In addition, the AI simultaneously predicts the strength of the reaction and a motivation change, and also outputs numerical simulation results such as “the motivation of department B decreases by an average of 20 points due to the integration policy”, “the leader layer of department A actively participates in the new system after the integration”, and “the defection risk of young employees of department C decreases due to the launch of the new project”. Furthermore, the AI can summarize the simulation results and present specific suggestions contributing to decision-making, such as “when the integration policy is implemented, the approval rate of department A is 80%, the opposition rate of department B is 60%, and an additional integration proposal is expected to be proposed from department C”, “due to the evaluation system change, the overall motivation temporarily decreases, but tends to recover after half a year”, and “due to the opening of the new base, the satisfaction level of employees living in rural areas significantly improves”. Furthermore, based on the simulation results, the AI can automatically propose an attribute layer or region with a high flaming risk, a blocking point of a diffusion route, an optimization proposal for a marketing policy, an improvement proposal for an information transmission route at the time of a disaster, and the like. Specifically, the simulation execution unit inputs a text vector of the policy proposal. The prediction model outputs a reaction probability distribution of each agent. The system determines a threshold value for this probability distribution to finalize a final prediction result.

The user interface unit visualizes the simulation results received from the server from various perspectives such as by department, by attribute, by individual, in chronological order, and by network. For example, it is possible to display “which department approves or opposes” color-coded in a heat map, display “motivation change” in chronological order in a bar graph, visualize “opinion propagation among employees having a strong influence relationship” in a network diagram, and show “reaction transition after policy implementation” in a timeline display. Furthermore, it is also possible to adjust parameters of the policy proposal (for example, “selection of departments subject to integration”, “details of the evaluation system”, “setting of the number of transferred persons”, “scale of the new project”, “welfare contents”, and the like) from the terminal and re-execute the simulation in real time. For example, various scenarios such as “when the integration target is changed to department A and department C”, “when an evaluation item of the evaluation system is added”, and “when the opening location of the new base is changed” can be immediately compared and examined. Furthermore, the user interface unit also includes a function of exporting the simulation results in a PDF, image, or table format, a function of searching and re-displaying past simulation histories, an automatic report generation function by AI, and the like. Specifically, the user interface unit receives structured simulation results as an input. The display processing unit generates and outputs image data for visualization. The system thereby improves user operability.

The database unit centrally manages agent data, communication history, simulation history, policy proposal history, AI learning data, and the like. For example, by accumulating past simulation results and continuously learning by the AI, simulation accuracy can be improved. The AI learning management unit is responsible for management of an AI learning data set, creation of teacher data, construction of a feedback loop, version management of an AI model, and the like, and feeds back actual data such as, for example, “actual turnover rate after past policy implementation”, “actual motivation transition”, and “actual opinion distribution” to the AI to continuously improve the prediction accuracy of the AI. Specifically, the database unit stores various history data as structured data. The learning management unit updates weights of the model using the actual data as teacher data. The system reduces a prediction error by this learning process.

Specific examples of prompt sentences to be read into the generative AI necessary for implementing the present invention include, for example, “Based on the following employee data, when an integration policy of department A and department B is implemented, classify what kind of reaction each employee shows into categories such as approval, neutrality, opposition, defection, and new proposal, and output it with a reason”, “Analyze past meeting minutes and questionnaire results, and extract what kind of opinion tendency employees of department C have toward a new project”, “Input an evaluation system change proposal, predict a motivation change of all employees, and output it numerically by department and by title”, “When a topic of ‘new product announcement’ spreads on SNS, simulate what kind of reaction occurs by age, gender, region, and occupation in chronological order”, and “When specific information spreads on SNS at the time of a disaster, propose in which attribute layer misinformation is likely to spread, and an optimal route for accurate information transmission”. Specifically, the system inputs these prompt sentences as character string data. The large language model outputs a classification result and a predicted numerical value in a text format. The system analyzes the output text and passes it to a subsequent processing module.

As described above, the system according to the present embodiment includes the agent generation unit, the data analysis unit, the simulation execution unit, the user interface unit, the database unit, and the AI learning management unit, and each unit collects, analyzes, simulates, visualizes, and learns various data, thereby highly accurately and dynamically realizing simulation of complex human relations, opinion formation, motivation change, risk prediction, and social impact inside and outside the organization. Specifically, the system optimizes a data flow by linking each unit. The computer improves calculation efficiency by parallel processing. The system thereby realizes high-speed simulation even for large-scale organizational data.

### Implementation Steps

Step 1: Agent data generation. A wide variety of attribute information such as name, age, gender, title, affiliated department, years of service, transfer history, evaluation history, commendation/disciplinary history, qualification information, skill set, language ability, place of origin, family structure, commuting time, working style, and health checkup results is automatically acquired from a personnel management system and a business management system in an organization, and each member is modeled as a virtual agent. For example, an agent having detailed attributes such as a 45-year-old male who is a general manager of department A, has experienced transfer three times in the past, has a high recent evaluation, has taken leadership training, has a family of a spouse and two children, has a commuting time of one hour, and has an item requiring observation in a health checkup is generated.

Step 2: Unstructured data analysis and psychological parameter extraction. Using generative AI, personality tendencies, values, and psychological parameters of each agent are extracted from unstructured data such as past business daily reports, meeting minutes, internal SNS postings, questionnaire answers, and 1-on-1 interview records. For example, information such as “positive about new policies”, “conservative”, “risk-averse”, “highly cooperative”, “strongly self-assertive”, “low stress tolerance”, “emphasis on work-life balance”, “promotion-oriented”, “stability-oriented”, “challenge-oriented”, “current satisfaction level”, “future anxiety level”, and “trust level in the organization” is extracted and assigned as agent attributes. As a specific example of a prompt sentence to be read by the generative AI, “Analyze the following daily reports, meeting minutes, SNS postings, and questionnaire answers of employees, extract personality tendencies, values, and psychological parameters, and digitize them for each category” can be cited. Specifically, the present system analyzes unstructured data using a large language model. The present system tokenizes text data. The present system maps the tokenized data to a high-dimensional vector space. The present system calculates contextual dependencies using a self-attention mechanism. The present system receives a text array of business daily reports and meeting minutes as input data. The present system generates a probability distribution and a score of a psychological parameter as output data. The present system transmits the output score to a threshold determination module. The present system determines the attribute of the agent by threshold determination. The present system improves the speed and accuracy of data processing by these processes. The present system realizes objective parameter extraction excluding human subjectivity.

Step 3: Integration of communication history and extraction of influence relationships. Various communication histories such as e-mails, chats, SNS, business reports, meeting minutes, questionnaire results, employee satisfaction surveys, exit interview records, and internal event participation histories in the organization are collected and integrated, and natural language analysis is performed using generative AI. The AI automatically extracts opinion tendencies and emotional tendencies by department and by individual, and identifies a group of employees whose motivation has increased or a group of employees who have shown a defection tendency after a specific policy announcement using time-series analysis and sentiment analysis. Furthermore, the AI extracts an influence relationship network in the organization, and records an influence degree parameter such as “a general manager of department A has a strong influence on a section manager of department B” or “a leader of department C has a great influence on opinion formation of young employees”. As a specific example of a prompt sentence to be read by the generative AI, “Analyze the following intra-organizational communication history, extract opinion tendencies, emotional tendencies, and influence relationship networks of each department and individual, and digitize the degree of influence” can be cited. Specifically, the data analysis unit acquires unstructured text data from a distributed file system. The data analysis unit executes a natural language processing module. The natural language processing module tokenizes text data. The natural language processing module projects a token sequence into an embedding vector space. The present system includes a large language model based on a Transformer architecture. The large language model calculates dependencies between tokens using a self-attention mechanism. Input data to the large language model is a sequence of 512-dimensional word embedding vectors. As a specific example of the input data, a text vector of an e-mail sent by the general manager of department A can be cited. As another specific example of the input data, a time-series tensor of postings including a specific hashtag in the internal SNS can be cited. The large language model outputs an emotion polarity score of each employee. The large language model outputs a weight matrix of a directed graph indicating the degree of influence between employees. As a specific example of output data, a floating-point value of 0.85 indicating the degree of influence from the general manager of department A to the section manager of department B can be cited. As another specific example of the output data, a score of 0.72 indicating an approval probability for a specific policy can be cited. The data analysis unit stores the output weight matrix in a graph database. The simulation execution unit executes an information propagation simulation using this weight matrix as a subsequent process. This processing method does not depend on human subjective evaluation. This processing method quantifies an influence relationship by a matrix operation in a high-dimensional vector space. Thereby, the present system dramatically improves a calculation processing speed. The present system exhibits a technical effect of accurately modeling complex human relationships in a large-scale organization. As a specific application field, a task of identifying a key person accompanying organizational restructuring in a company can be cited.

Step 4: Policy proposal input and simulation condition setting. A user inputs a virtual policy proposal or topic, for example, “integration of department A and department B”, “launch of a new project”, “change in an evaluation system”, “large-scale personnel transfer”, “introduction of a new welfare system”, “expansion of a remote work ratio”, “opening of a new base”, “change of top management”, “launch of a new product”, “response at the time of occurrence of a scandal”, and the like from a terminal, and finely sets simulation conditions. For example, selection of departments to be integrated, details of an evaluation system, the number of transferred persons, the scale of a new project, welfare contents, and the like can be designated as parameters. Specifically, the user interface unit receives a policy parameter group via an input device. The policy parameter group is encoded as a multidimensional numerical vector. The present system normalizes the input policy parameter group. The present system transfers the normalized parameter group to the simulation execution unit. The simulation execution unit converts the policy parameter group into a condition vector. The condition vector is a 256-dimensional continuous value vector. As a specific example of input data, a one-hot vector of a categorical variable indicating department integration can be cited. As another specific example of the input data, a floating-point value obtained by scaling an integer value indicating the number of transferred persons can be cited. The present system couples these condition vectors to an input layer of a subsequent prediction model. The present system verifies the validity of parameters in real time via a graphical user interface. The present system immediately returns an error code in response to an invalid parameter input. This processing method executes a rule-based input verification algorithm. Thereby, the present system prevents a calculation error in a subsequent simulation process. The present system exhibits a technical effect of suppressing consumption of useless calculation resources. As a specific application field, a next-year organizational structure simulation task in a corporate planning department can be cited.

Step 5: Reaction prediction simulation by generative AI. Using generative AI on the server side, what kind of reaction each agent shows to a policy or topic is predicted. The AI comprehensively considers attribute parameters of an agent, past reaction tendencies, an influence relationship network in an organization, a sentiment analysis result of policy contents, data at the time of a similar policy in the past, and the like, and probabilistically calculates reactions such as “approval”, “neutrality”, “opposition”, “defection”, “new proposal”, “silence”, “passive approval”, and “active opposition”. As specific examples of a prompt sentence to be read by the generative AI, “Based on the following agent attribute data and policy proposal, classify what kind of reaction each agent shows by category, and output it together with a reason” and “When policy proposal A is implemented, predict a motivation change by department, by title, and by individual, and output it as a numerical value” can be cited. Specifically, the simulation execution unit drives a reaction prediction neural network. The reaction prediction neural network has a composite architecture of a multilayer perceptron and a recurrent neural network. Input data to the reaction prediction neural network is a feature amount tensor obtained by combining an attribute vector of an agent and a condition vector of a policy. As a specific example of the input data, a 128-dimensional attribute vector including age and years of service can be cited. As another specific example of the input data, time-series array data indicating a reaction history to a past policy can be cited. The reaction prediction neural network applies a softmax function to output a probability distribution of each reaction category. As a specific example of output data, a probability distribution vector indicating an approval probability of 0.6, a neutrality probability of 0.3, and an opposition probability of 0.1 can be cited. As another specific example of the output data, a continuous value score of minus 15.5 indicating a motivation change amount can be cited. The simulation execution unit executes sampling by a Monte Carlo method based on the output probability distribution. The simulation execution unit records a sampling result in a memory as a confirmed state of each agent. The present system optimizes a weight parameter of the reaction prediction neural network using a cross-entropy error function. The present system executes a learning process by a gradient descent method. This processing method excludes prediction by human intuition. This processing method calculates an interaction of nonlinear features in a high-dimensional space. Thereby, the present system significantly improves prediction accuracy. The present system exhibits a technical effect of efficiently executing parallel calculation of a large-scale agent group on a graphics processing unit. As a specific application field, an employee reaction prediction task at the time of a large-scale personnel system revision in a human resources department can be cited.

Step 6: Aggregation, summarization, and visualization of simulation results. The generative AI summarizes simulation results and presents specific suggestions contributing to decision-making, such as “when the integration policy is implemented, the approval rate of department A is 80%, the opposition rate of department B is 60%, and an additional integration proposal is expected to be proposed from department C”, “due to the evaluation system change, the overall motivation temporarily decreases, but tends to recover after half a year”, and “due to the opening of a new base, the satisfaction level of employees living in rural areas significantly improves”. The user interface unit visualizes the results using a heat map, a bar graph, a network diagram, a timeline display, and the like from various perspectives such as by department, by attribute, by individual, in chronological order, and by network. As specific examples of a prompt sentence to be read by the generative AI, “Summarize the following simulation result data, extract important points for decision makers, and output them in a report format” and “Generate a data set for graphing the simulation results by department, by attribute, and in chronological order” can be cited. Specifically, the simulation execution unit aggregates reaction state vectors of all agents. The simulation execution unit inputs the aggregated data to a statistical processing module. The statistical processing module calculates an average value and a variance by department and by attribute. The present system includes a decoder network specialized for natural language generation. Input data to the decoder network is a multidimensional array of aggregated statistical values. As a specific example of the input data, a numerical data array indicating the approval rate of department A can be cited. As another specific example of the input data, a two-dimensional tensor indicating a time-series motivation transition can be cited. The decoder network assigns a weight to an important statistical value using an attention mechanism. The decoder network outputs a token sequence of a summary text. As a specific example of output data, a natural language text character string pointing out a bias in the approval rate can be cited. As another specific example of the output data, a character string of a warning message identifying an attribute group with a high defection risk can be cited. The user interface unit renders the output text character string on a display device. The user interface unit converts the statistical value array into color space data to generate a heat map. This processing method automatically converts massive simulation results into a human-interpretable format. Thereby, the present system dramatically reduces the time required for data analysis. The present system exhibits a technical effect of reducing a cognitive load in a decision-making process. As a specific application field, a dashboard display task of simulation results in a management meeting can be cited.

Step 7: Accumulation of simulation results and AI learning feedback. A database unit centrally manages agent data, communication history, simulation history, policy proposal history, AI learning data, and the like, and an AI learning management unit feeds back actual result data such as an actual turnover rate, an actual motivation transition, and an actual opinion distribution after implementation of a past policy to the AI, and continuously improves the prediction accuracy of the AI. For example, a prompt sentence “Make the AI learn actual result data after implementation of a past policy to improve future simulation accuracy” can be used. Specifically, the database unit executes a relational database management system. The database unit writes tensor data of simulation results to a persistent storage. The AI learning management unit periodically executes an actual result data collection batch process. The AI learning management unit constructs a learning data set by pairing actual result data and past prediction data. The present system activates a re-learning process of a prediction model. Input data to the re-learning process is an error vector between a predicted value and an actual value. As a specific example of the input data, a numerical array indicating a difference between a predicted turnover rate and an actual turnover rate can be cited. As another specific example of the input data, a time-series tensor indicating a difference between a predicted motivation score and an actual questionnaire result can be cited. The present system updates a weight of a neural network using a backpropagation method. The present system calculates a mean square error as a loss function. The present system saves the updated weight matrix as a new model version. As a specific example of output data, a binary file including an optimized group of millions of parameters can be cited. As another specific example of the output data, transition graph data of a loss value indicating a convergence state of learning can be cited. The present system loads the latest model version in a subsequent simulation. This processing method is different from a static rule-based system. This processing method completes a continuous self-optimization loop based on actual data inside a computer. Thereby, the present system autonomously improves prediction accuracy over time. The present system exhibits a technical effect of enhancing adaptability of a model to environmental changes. As a specific application field, continuous organizational monitoring and an automatic tuning task of a prediction model can be cited.

### Specific Use Case

For example, when considering an integration policy of department A and department B in an organization, first, the agent generation unit acquires attribute information such as names, ages, genders, titles, affiliated departments, years of service, past transfer histories, evaluation histories, commendation/disciplinary histories, qualification information, skill sets, language abilities, places of origin, family structures, commuting times, working styles, and health checkup results of all members of department A and department B from a personnel management system, and models each member as a virtual agent. Furthermore, the generative AI analyzes unstructured data such as past business daily reports, meeting minutes, internal SNS postings, questionnaire answers, and 1-on-1 interview records, extracts personality tendencies, values, and psychological parameters (e.g., positiveness toward new policies, conservativeness, risk aversion, cooperativeness, strength of self-assertion, stress tolerance, emphasis on work-life balance, promotion orientation, stability orientation, challenge orientation, current satisfaction level, future anxiety level, trust level in the organization, etc.) of each agent, and assigns them as agent attributes. Next, the data analysis unit collects communication history such as e-mails, chats, SNS, business reports, meeting minutes, questionnaire results, employee satisfaction surveys, exit interview records, and internal event participation history in the organization, and the generative AI performs natural language analysis to extract opinion tendencies and emotional tendencies by department and by individual, and an influence relationship network (e.g., a general manager of department A has a strong influence on a section manager of department B). Specifically, the agent generation unit issues an SQL query to a personnel database. The agent generation unit converts the acquired attribute record into a structured data format. The agent generation unit normalizes each attribute value and generates a feature amount vector for each agent. The present system analyzes unstructured data using a natural language processing model. Input data to the natural language processing model is a token sequence of a text document. As a specific example of the input data, a text vector extracted from a past business daily report can be cited. As another specific example of the input data, a word embedding tensor converted from a voice recognition result of a 1-on-1 interview record can be cited. The natural language processing model estimates a psychological parameter of each agent. The natural language processing model outputs a multidimensional psychological feature amount vector. As a specific example of output data, a score of 0.8 indicating positiveness toward a new policy can be cited. As another specific example of the output data, a normalized numerical value of 0.4 indicating stress tolerance can be cited. The agent generation unit combines a basic attribute vector and a psychological feature amount vector to construct an integrated agent vector. The data analysis unit parses a log file of communication history. The data analysis unit generates an adjacency matrix in which identifiers of a sender and a receiver are nodes and a communication frequency is a weight of an edge. The present system processes the adjacency matrix using a graph convolutional network. The present system calculates an influence degree score between nodes. This processing method completely excludes manual data classification by humans. This processing method maps heterogeneous mixed data to the same high-dimensional vector space. Thereby, the present system converts complex human relationships and psychological states into a format computable by a computer. The present system exhibits technical effects of automation of data processing and improvement of calculation efficiency. As a specific application field, an employee profiling task at the time of organizational integration accompanying M&A can be cited.

A user inputs a policy proposal “integration of department A and department B” from a terminal, and sets simulation conditions such as departments to be integrated, an organizational structure after integration, title assignment, the number of transferred persons, change contents of an evaluation system, and a unification policy of welfare in detail. The simulation execution unit predicts what kind of reaction each agent shows to the integration policy using the generative AI, and probabilistically calculates reactions such as approval, neutrality, opposition, defection, new proposal, silence, passive approval, and active opposition. For example, a management layer of department A has a strong tendency to approve the integration, young employees of department B show a strong opposition or defection tendency, and some employees of department C may make a new proposal that “our own department should also be subject to integration”. Furthermore, the AI simultaneously predicts the strength of a reaction and a motivation change, and outputs numerical simulation results such as “the motivation of department B decreases by an average of 20 points due to the integration policy”, “a leader layer of department A actively participates in a new structure after the integration”, and “a turnover risk of department B temporarily increases immediately after the announcement of the integration policy”. Specifically, the terminal packages the input policy conditions into a payload in a JSON format. The terminal transmits the payload to a server via a secure communication protocol. The simulation execution unit decodes the payload and generates a policy feature amount tensor. The simulation execution unit executes an inference phase of a prediction neural network. Input data to the prediction neural network is batch data of integrated agent vectors of all agents and the policy feature amount tensor. As a specific example of the input data, matrix data of 1000 rows and 256 columns indicating attributes of all employees of department A can be cited. As another specific example of the input data, a 64-dimensional condition vector encoding change contents of an evaluation system can be cited. The prediction neural network outputs a probability distribution of a reaction category and a motivation change amount of each agent. As a specific example of output data, a score of 0.85 indicating a probability that a specific young employee defects can be cited. As another specific example of the output data, average change amount data of minus 20.0 indicating a motivation decrease of the entire department B can be cited. The simulation execution unit determines a final reaction state of each agent based on the output probability distribution. The simulation execution unit writes the determined reaction state to a result database. This processing method utilizes nonlinear mapping by a deep learning model instead of simple linear regression. Thereby, the present system realizes highly accurate prediction even in a situation where a plurality of policy parameters are complexly intertwined. The present system exhibits a technical effect of improving an inference speed by processing a large-scale matrix operation in parallel. As a specific application field, a risk assessment task at the time of large-scale organizational restructuring can be cited.

The user interface unit visualizes the simulation result from various perspectives such as by department, by attribute, by individual, in chronological order, and by network using a heat map, a bar graph, a network diagram, a timeline display, and the like, and enables a decision maker to intuitively grasp which department approves or opposes, an employee of which attribute has a defection risk, and how a motivation transition after implementation of a policy will be. Furthermore, the user can change parameters such as details of an integration target department and an evaluation system, re-execute the simulation in real time, and compare and examine a plurality of scenarios. The database unit centrally manages agent data, communication history, simulation history, policy proposal history, AI learning data, and the like, and the AI learning management unit feeds back performance data such as an actual turnover rate, an actual motivation transition, and an actual opinion distribution after implementation of a past policy to the AI, and continuously improves prediction accuracy of the AI. Specifically, the user interface unit reads tensor data of the simulation result from a result database. The user interface unit executes a data conversion module to generate a data structure for drawing. The user interface unit calls a graphics library to render pixel data on a screen. The system detects a parameter change request from the user with an event listener. The system issues a recalculation command to the simulation execution unit based on the changed parameter. The database unit manages data using a distributed key-value store. The AI learning management unit includes a module configured to calculate a difference between the performance data and prediction data. Input data to the AI learning management unit are a past simulation result vector and an actual observation value vector. As a specific example of the input data, a predicted approval rate array by department and an actual questionnaire aggregation result array can be cited. As another specific example of the input data, an integer value of the predicted number of defectors and an integer value of the actual number of defectors can be cited. The AI learning management unit calculates a gradient of a loss function using these input data. The AI learning management unit generates output data for fine-tuning a weight parameter of a prediction model. As a specific example of the output data, a gradient matrix indicating a weight update amount of each neuron can be cited. As another specific example of the output data, a scalar value for dynamically adjusting a learning rate can be cited. The system deploys the updated model on a memory to prepare for next inference. This processing method integrates interactive data visualization and continuous learning in a background. Thereby, the system maintains the accuracy of the model while minimizing a waiting time of the user. The system exhibits a technical effect of achieving both response performance of the entire system and prediction accuracy. As a specific application field, an operation task of a real-time decision-making support dashboard for a management layer can be cited.

Specific examples of a prompt sentence to be read by the generative AI include “Based on the following employee data and communication history, when an integration policy of department A and department B is implemented, classify what kind of reaction each employee shows into categories such as approval, neutrality, opposition, defection, and new proposal, and output it together with a reason”, “Analyze past meeting minutes and questionnaire results, and extract what kind of opinion tendency the employees of department B have toward the integration policy”, “With an integration policy proposal as an input, predict a motivation change of all employees, and output it as a numerical value by department and by title”, and “Generate a data set for graphing a simulation result by department, by attribute, and in chronological order”. Specifically, the system includes a prompt generation module. The prompt generation module dynamically constructs a text character string using a template engine. The prompt generation module serializes an attribute vector of an agent and a statistical value of communication history extracted from a database into a text format. The system inserts the serialized data into a placeholder of a prompt template. The system transmits the constructed prompt character string to an API endpoint of a large language model. Input data to the large language model is a token sequence including a natural language command sentence and a character string representation of structured data. As a specific example of the input data, a character string in a JSON format including employee data of department A can be cited. As another specific example of the input data, a long character string obtained by concatenating text data of past meeting minutes can be cited. The large language model executes an autoregressive decoding process. The large language model outputs a text character string of an analysis result or a prediction result according to a designated format. As a specific example of the output data, text data in a CSV format describing a reaction category and a reason of each employee can be cited. As another specific example of the output data, a JSON array including coordinate data for graph drawing can be cited. The system parses the output text data and maps it to an internal data structure. The system passes the mapped data to a subsequent visualization process or aggregation process. This processing method incorporates an inference capability of the large language model into a data pipeline inside the system. Thereby, the system extracts structured data from unstructured data with high accuracy. The system exhibits a technical effect of dramatically improving flexibility and expandability of data processing. As a specific application field, an automatic generation task of a complex data query using a natural language interface can be cited.

In this way, by using the system of the present invention, it is possible to multilaterally and quantitatively predict and visualize a reaction, a motivation change, a defection risk, an opinion distribution, a necessity of an additional policy, and the like of each member before implementation of an organizational reform policy, and a decision maker can quickly and accurately formulate an optimal policy proposal while comparing and examining a plurality of scenarios. Specifically, the system adopts a distributed processing architecture in which a plurality of calculation nodes are linked. The system implements each task of agent generation, data analysis, and simulation execution as a microservice. The system controls asynchronous communication between the respective services via a message queue. Input data to the system is a stream of raw data collected from various systems in an organization. As a specific example of the input data, a CSV file of an employee master exported daily from a personnel system can be cited. As another specific example of the input data, a JSON payload of a message streamed in real time from an internal chat system can be cited. The system processes these input data in real time and continuously updates a simulation model. The system executes a batch process for evaluating a plurality of policy scenarios in parallel. The system outputs an evaluation score of each scenario. As a specific example of the output data, a numerical value of 0.25 indicating a comprehensive risk score of policy A can be cited. As another specific example of the output data, a numerical value of plus 12.0 indicating an expected motivation improvement amount of policy B can be cited. The system compares these output results and executes an algorithm for automatically recommending an optimal scenario. This processing method exhaustively calculates a combination of large-scale and complex variables exceeding human cognitive limits. Thereby, the system ensures objectivity and promptness of decision-making. The system exhibits a technical effect of preventing a fatal error in organizational management and realizing efficient use of calculation resources. As a specific application field, a change management task at the time of promoting company-wide digital transformation in a large enterprise can be cited.

(Application Example 1) The flow of the specific processing in Application Example 1 will be described. Each part of the system described below is realized by the data processing device 12 and the smart device 14. Additionally, the data processing device 12 is referred to as a “server,” and the smart device 14 is referred to as a “terminal.”

### Embodiment for Carrying Out the Present Invention

Embodiments of the present invention will be described more specifically and in detail. The system of the present invention is composed of a plurality of functional units such as an agent generation unit, a data analysis unit, a simulation execution unit, a user interface unit, a database unit, and an AI learning management unit in order to highly accurately and dynamically simulate reactions and behaviors of various members in city management. Specifically, the system includes a scalable server cluster constructed on a cloud computing environment. The server cluster distributes a request from a terminal to each functional unit via a load balancer. The agent generation unit constructs a virtual space on a memory and instantiates agent objects on a scale of millions. The data analysis unit processes petabyte-class city data in parallel using a distributed data processing framework. The simulation execution unit accelerates a large-scale matrix operation by utilizing a tensor core of a graphics processing unit. Input data to the system is a sensor data stream from an IoT device group arranged in a city. As a specific example of the input data, video tensor data of 30 frames per second acquired from a camera at an intersection can be cited. As another specific example of the input data, time-series array data of power consumption transmitted from a smart meter at 5-minute intervals can be cited. The system preprocesses these input data in real time and converts them into a feature vector. The system integrates processing results of the respective functional units and outputs a state vector indicating a dynamic state of the entire city. As a specific example of the output data, a normalized score of 0.8 indicating a current congestion degree of a specific area can be cited. As another specific example of the output data, a multidimensional tensor indicating a predicted value of an environmental load can be cited. The database unit stores these output data in a time-series database to prepare for a subsequent analysis query. This processing method realizes a dynamic simulation based on real-time data, unlike a conventional static city planning model. Thereby, the system minimizes a response delay to a rapid change in a city environment. The system exhibits a technical effect of maximizing a calculation throughput in a large-scale simulation. As a specific application field, an operation task of an integrated city operation center in a smart city can be cited.

The agent generation unit models all entities constituting a city as virtual agents. For example, various attribute information related to city life, such as age, gender, place of residence, family structure, health condition, commuting means, owned vehicle, environmental awareness, motivation, satisfaction level, SNS usage frequency, purchasing tendency, participation degree in a local community, evacuation tendency at the time of a disaster, past event participation history, administrative service use history, hobby/interest field, presence or absence of a pet, type of housing (detached house/apartment complex), remote work implementation status, and child-rearing status, is assigned to a resident agent. For example, an agent having detailed attributes such as a 35-year-old male resident living in Kita Ward, living with a spouse and two children, commuting by bicycle, having high environmental awareness, frequently transmitting local information on SNS, having experience of participating in a disaster drill and a local cleaning activity in the past, having an item requiring observation in a health checkup, keeping a dog as a pet, living in a condominium, and implementing remote work twice a week is generated. An administrative staff agent is provided with attributes such as an affiliated department, a task in charge, years of service, policy orientation, past policy achievements, contact frequency with residents, working style (field/main office), response experience at the time of a disaster, an administrative evaluation score, training attendance history, and transfer history. A commercial facility operator agent is also assigned a store scale, an industry type, the number of employees, a sales transition, sponsorship history for a local event, participation status in an environmental policy, business hours, location characteristics, a trade area population, point card introduction status, presence or absence of SNS sales promotion activities, a business continuity plan at the time of a disaster, commuting means of employees, a tenant contract form, and the like. A tourist or temporary stayer agent is provided with attributes such as a place of origin, a purpose of stay, a period of stay, an accommodation facility, moving means, tourist spot visit history, information collection means (SNS, tourist information center, word of mouth), a consumption tendency, an accompanying person attribute, past city visit experience, and an evacuation behavior tendency at the time of a disaster. Furthermore, for a support personnel agent at the time of a disaster, an affiliated organization, a specialized field, dispatch experience, a stayable period, a cooperating institution, past disaster response achievements, types of equipment and materials, means of arrival at a site, information communication means, and the like are set in detail. Specifically, the agent generation unit acquires various data sets from an open data portal of an administration or a data lake of a private enterprise. The agent generation unit executes an algorithm for cleansing the acquired data and complementing a missing value. The agent generation unit encodes the attribute of each entity as a multidimensional feature vector. The system learns a correlation between complex attributes using an encoder network of the generative AI. Input data to the encoder network is a record array including raw data of each entity. As a specific example of the input data, a numerical vector having elements such as age, gender, place of residence, and annual income of a resident can be cited. As another specific example of the input data, a mixed tensor of categorical data and numerical data including business hours and a store area of a commercial facility can be cited. The encoder network maps these input data to a low-dimensional latent space. The encoder network outputs a latent representation vector of each agent. As a specific example of the output data, a 256-dimensional floating-point vector expressing a behavioral characteristic of a resident can be cited. As another specific example of the output data, a 128-dimensional vector indicating a response capability of support personnel at the time of a disaster can be cited. The agent generation unit allocates this latent representation vector to a memory as a property of an agent object. The simulation execution unit calculates an interaction between agents using this latent representation vector in a subsequent process. This processing method eliminates rule-based attribute allocation and adopts a data-driven approach. Thereby, the system faithfully reproduces complex diversity of the real world in a computer model. The system exhibits a technical effect of improving modeling accuracy of an agent and enhancing reality conformity of a simulation. As a specific application field, a behavior change prediction task of a resident in a city development plan can be cited.

The data analysis unit collects information from various data sources inside and outside the city, and analyzes it using the generative AI. For example, as various sensor data in the city, a traffic volume sensor (major intersection, arterial road, station square, around a commercial facility), an environmental sensor (air quality, noise, temperature, humidity, precipitation, ultraviolet ray amount), a disaster prevention sensor (river water level, seismometer, sediment disaster monitoring), a congestion degree sensor (station premises, bus stop, event venue, commercial facility), an energy consumption sensor (public facility, commercial facility, housing), a garbage discharge amount sensor (garbage collection point, recycling base), and the like can be cited. As administrative records, policy implementation history, resident questionnaires, administrative procedure history, complaint/request records, local meeting minutes, administrative evaluation reports, disaster response records, public facility use history, subsidy application history, city planning materials, and the like are collected. SNS postings include local community postings, event announcements, information diffusion at the time of a disaster, word of mouth, transmission from an official administrative account, opinion expression of residents, experience postings of tourists, sales promotion postings of commercial facilities, operation information of transportation facilities, volunteer recruitment information, and the like. As traffic history, public transportation use history (IC card data, commuter pass use, boarding/alighting history), road congestion data (real-time, past statistics), parking lot use history, shared bicycle use history, taxi dispatch history, traffic accident occurrence records, school route use status, and the like are integrated. As commercial activity history, purchasing data, point card use history, event participation history, campaign reactions, sales transitions, visitor attributes, trade area analysis data, electronic payment use history, congestion degree data of commercial facilities, and the like are collected. As disaster response records, evacuation shelter use history, relief supply distribution history, evacuation behavior logs, damage situation reports, disaster volunteer activity records, communication failure occurrence history at the time of a disaster, communication history between administration and residents, and the like are collected. As external questionnaire results, tourist satisfaction surveys, event participant questionnaires, city brand surveys, prospective immigrant questionnaires, awareness surveys of foreign tourists, transportation user questionnaires, and the like are utilized. The generative AI analyzes these massive amounts of data by methods such as natural language processing, time-series analysis, emotion analysis, clustering, network analysis, anomaly detection, and pattern mining, and extracts opinion tendencies, emotional tendencies, influence relationships, information propagation routes, and behavior patterns by role, by region, and by individual, such as “residents of Kita Ward have a strong interest in expanding bicycle infrastructure”, “commercial facility operators in Minami Ward are positive about holding a large-scale event”, “administrative staff in Chuo Ward feel a challenge in information transmission at the time of a disaster”, “tourists emphasize information collection on SNS”, “the elderly strongly request improvement in convenience of public transportation”, “the youth have a high motivation to participate in an event”, and “foreign tourists emphasize multilingual guide displays”. Furthermore, the AI also analyzes changes in chronological order, satisfaction level/motivation changes after implementation of a specific policy, an increase in a defection risk, a speed and range of information diffusion, real-time changes in evacuation behavior at the time of a disaster, occurrence timing of traffic congestion at the time of holding an event, and the like, and dynamically updates agent attributes and the state of the entire city. Specifically, the data analysis unit operates a data ingest pipeline. The data ingest pipeline asynchronously fetches data from various sensors and external APIs. The data analysis unit synchronizes the collected data with a time stamp to construct a multidimensional time-series tensor. The system executes a hybrid AI architecture combining a long short-term memory network specialized for time-series analysis and a Transformer model for natural language processing. Input data to the hybrid AI is a multimodal stream of numerical data of sensors and text data. As a specific example of the input data, an hourly integer value array indicating a traffic volume at a major intersection can be cited. As another specific example of the input data, a token embedding matrix of text data regarding a local event scraped from SNS can be cited. The hybrid AI integrally processes these input data to detect a latent pattern and an abnormal value. The hybrid AI outputs a transition of an emotion score and a behavior probability of each agent. As a specific example of the output data, a score of 0.92 indicating an interest degree of Kita Ward residents in bicycle infrastructure can be cited. As another specific example of the output data, a predicted value of 0.85 indicating a traffic congestion occurrence probability at the time of holding a specific event can be cited. The data analysis unit dynamically updates the attribute vector of the agent using the output analysis result. The system synchronizes the updated agent data to the database unit. This processing method integrally analyzes heterogeneous big data in the same latent space. Thereby, the system extracts a complex causal relationship that cannot be discovered by a single data source. The system exhibits a technical effect of grasping a dynamic state change of a city in real time and reducing latency of data processing. As a specific application field, traffic management and disaster prevention monitoring tasks of a city can be cited.

The simulation execution unit receives a virtual policy proposal such as a city policy, an infrastructure policy, a traffic regulation, a disaster countermeasure, and an event holding as an input, and predicts what kind of reaction or behavior each agent shows to the policy proposal using the generative AI. For example, when a “bicycle-dedicated road expansion” policy is input, various reactions are obtained by role and by attribute, such that among resident agents, bicycle commuters and a group with high environmental awareness actively approve, car commuters and commercial facility operators oppose, administrative staff are neutral or approve, traffic managers approve or propose, and tourists pay attention as a new tourism resource. The AI simultaneously simulates a motivation or satisfaction level change, a defection risk, an additional proposal, an information diffusion behavior (SNS posting, word of mouth, event participation declaration, etc.), and a moving behavior (commuting route change, movement to an event venue, evacuation behavior, etc.) of each agent. For example, in a “large-scale event holding” policy, a complex reaction distribution is obtained, such that commercial facility operators and traffic managers approve or actively participate, some residents oppose due to congestion and noise, tourists actively participate, and administrative staff approve while being concerned about an increase in an operation burden. In a disaster countermeasure policy, various behaviors are simulated, such that evacuation shelter operators and medical workers actively respond, residents take evacuation behavior and information collection behavior, traffic managers take traffic regulation and guidance behavior, tourists are confused due to lack of information and diffuse information on SNS, and support personnel at the time of a disaster take cooperative behavior after arriving at a site. Furthermore, the AI also considers a combination of policies and a change in chronological order, and can highly accurately predict an influence of an interaction of a plurality of policies, such as “when a public transportation discount policy is implemented simultaneously with bicycle-dedicated road expansion”, “when event holding and traffic regulation are implemented simultaneously”, and “when evacuation shelter expansion and information transmission enhancement are performed simultaneously at the time of a disaster”. Specifically, the simulation execution unit executes a multi-agent reinforcement learning algorithm. The simulation execution unit calculates movement and information transmission of an agent in cooperation with a physics engine of a virtual city environment. The system models a policy proposal as a change in a reward function or a constraint condition of an environment. Input data to the simulation execution unit are a policy parameter vector and a current state tensor of all agents. As a specific example of the input data, a numerical vector indicating an expansion distance and a budget scale of a bicycle-dedicated road can be cited. As another specific example of the input data, array data of geospatial coordinates indicating an evacuation shelter opening position at the time of a disaster can be cited. The simulation execution unit evaluates an action policy network of each agent and calculates an action probability at a next time step. The simulation execution unit outputs an action selection result and a state change of each agent. As a specific example of the output data, a score of 0.75 indicating a probability that a specific resident agent changes from car commuting to bicycle commuting can be cited. As another specific example of the output data, a tensor of trajectory data indicating a group of agents heading to a specific evacuation shelter at the time of a disaster can be cited. The simulation execution unit aggregates these output data and calculates a macro index of the entire city. The system streaming-transmits the calculated index to the user interface unit. This processing method calculates autonomous decision-making of individual agents bottom-up, rather than a static equation-based model. Thereby, the system highly accurately predicts an emergent phenomenon and an unexpected bottleneck. The system exhibits a technical effect of efficiently calculating a non-linear interaction in a complex network. As a specific application field, a formulation task of a crowd guidance plan at the time of holding a large-scale event can be cited.

The user interface unit visualizes the simulation result from various perspectives such as by role, by region, by individual, in chronological order, and by network. For example, it is possible to color-code and display “which region approves or opposes” with a heat map, display “a change in motivation or satisfaction level” in chronological order with a bar graph, visualize “an information propagation route and an influence relationship” with a network diagram, and indicate “a reaction transition after implementation of a policy” with a timeline display. Furthermore, the user can adjust parameters of a policy proposal (e.g., target region, policy scale, budget allocation, traffic regulation range, event holding schedule, disaster countermeasure content, subsidy amount, information transmission means, number of evacuation shelters, medical system enhancement measure, etc.), re-execute the simulation in real time, and compare and examine a plurality of scenarios. For example, various scenarios can be instantly compared, such as “when a target region of bicycle-dedicated road expansion is changed from Kita Ward to Chuo Ward”, “when an event holding schedule is changed from a weekday to a holiday”, “when the number of evacuation shelters for disaster countermeasures is increased”, “when a target age of a public transportation discount policy is expanded”, and “when traffic regulation is relaxed simultaneously with extension of business hours of a commercial facility”. Furthermore, the user interface unit also includes a function of exporting the simulation result in a PDF, image, or table format, a function of searching and re-displaying past simulation history, an automatic report generation function by AI, a point extraction function for a decision maker, a risk alert notification function, and the like. Specifically, the user interface unit drives a WebGL-based rendering engine. The user interface unit maps multidimensional tensor data received from the simulation execution unit to a visual property. The system filters data to be drawn at high speed using a spatial index. Input data to the user interface unit is a structured data stream including position coordinates of an agent, a state score, and a weight of a network edge. As a specific example of the input data, an aggregated value array for each grid indicating a ratio of approval/opposition in each region can be cited. As another specific example of the input data, list data of nodes and edges indicating a route of information propagation can be cited. The user interface unit processes these input data and determines a pixel color and a shape of an object on a screen. The user interface unit captures a parameter change operation from the user and generates a difference vector. The user interface unit transmits the difference vector to the simulation execution unit and triggers recalculation. The system generates output data for instantly reflecting the recalculated result on the screen. As a specific example of the output data, texture data of an updated heat map indicating a traffic congestion degree after change can be cited. As another specific example of the output data, binary data of a PDF file including point text automatically generated for a decision maker can be cited. This processing method seamlessly integrates advanced graphics processing on a client side and distributed computing on a server side. Thereby, the system prevents a decrease in a frame rate in visualization of massive amounts of data. The system exhibits a technical effect of supporting interactive exploration by the user and dramatically improving responsiveness of an operation. As a specific application field, a presentation task for residents at a public hearing of city planning can be cited.

The database unit centrally manages agent data, city data, communication history, simulation history, policy proposal history, AI learning data, performance data, external cooperation data, and the like. For example, past simulation results, resident satisfaction survey results after actual policy implementation, the number of event participants, traffic volume changes, evacuation behavior logs at the time of a disaster, topic diffusion history on SNS, sales transitions of commercial facilities, administrative evaluation reports, and the like are accumulated, and the AI continuously learns, thereby improving simulation accuracy. The AI learning management unit is responsible for management of a learning data set of the AI, creation of teacher data, construction of a feedback loop, version management of an AI model, external AI cooperation, update of an anomaly detection model, parameter optimization, automatic scenario generation, and the like, and operations such as “making the AI learn performance data after implementation of a past policy to improve future simulation accuracy”, “making the AI learn an actual evacuation behavior log at the time of a disaster to enhance accuracy of evacuation behavior prediction”, and “making the AI learn topic diffusion history on SNS to improve accuracy of information propagation prediction” are possible. Specifically, the database unit adopts a hybrid configuration of a distributed NoSQL database and a data warehouse. The database unit distributes and arranges petabyte-scale data to a plurality of storage nodes using a sharding technology. The AI learning management unit schedules a batch job for periodically extracting a learning data set from the data warehouse. Input data to the AI learning management unit is tensor data including a pair of a past simulation predicted value and an actual observation value. As a specific example of the input data, a time-series array of a predicted traffic volume and an actual sensor measurement value at the time of a past event can be cited. As another specific example of the input data, a numerical vector of a predicted satisfaction level score before policy implementation and a questionnaire result after implementation can be cited. The AI learning management unit calculates an error function of a prediction model using these input data. The AI learning management unit updates a weight parameter of a neural network using a gradient descent method. The AI learning management unit outputs a weight matrix of an optimized new model. As a specific example of the output data, an updated group of millions of parameters of an evacuation behavior prediction model can be cited. As another specific example of the output data, numerical data of an evaluation metric indicating accuracy improvement of an information propagation prediction model can be cited. The system deploys the new model to the simulation execution unit and restarts an inference engine. This processing method eliminates static model operation and realizes continuous integration based on real-world feedback. Thereby, the system automatically adapts to an aging change and a new trend of a city environment. The system exhibits a technical effect of preventing long-term deterioration of prediction accuracy and ensuring reliability over the entire life cycle of the system. As a specific application field, an automatic operation and maintenance task of a prediction model in a smart city infrastructure can be cited.

In addition, the system of the present invention generates not only members in the city but also tourists and temporary stayers from the outside, support personnel at the time of a disaster, event participants, and the like in large quantities as virtual agents, and can also simulate an inflow from outside the city and a social ripple effect. For example, when a tourism policy is implemented, a dynamic interaction with the outside of the city can be highly accurately predicted, such as from which region tourists of what kind of attributes flow in, which facilities they use, and what kind of information they transmit on SNS, from which region and how many participants gather at the time of holding an event, and what kind of influence is exerted on traffic congestion and accommodation facility use, and how external support personnel are dispersed in the city and which evacuation shelter or medical institution they concentrate on at the time of a disaster. Furthermore, the AI also considers a combination of policies and a change in chronological order, and can highly accurately predict an influence of an interaction of a plurality of policies. Specifically, the agent generation unit acquires dynamic data outside the city in cooperation with an API of an external data provider. The agent generation unit dynamically instantiates an external agent based on the acquired data. The system accelerates a neighborhood search of agents inside and outside the city using a spatial hash algorithm. Input data to the simulation execution unit are a state tensor of an agent in the city and an inflow parameter vector of an external agent. As a specific example of the input data, two-dimensional array data indicating attributes and arrival times of tourists flowing in in response to a tourism campaign can be cited. As another specific example of the input data, a feature vector indicating a skill set and equipment of support personnel dispatched from an adjacent municipality at the time of a disaster can be cited. The simulation execution unit integrates these input data and calculates collision determination and resource competition between agents. The simulation execution unit outputs an action trajectory of the external agent and a load status on infrastructure in the city. As a specific example of the output data, time-series heat map data indicating a rapid increase in pedestrian density around a specific tourist spot can be cited. As another specific example of the output data, a congestion score of a network indicating that support personnel at the time of a disaster concentrate on a specific medical institution can be cited. The system records these output results in the database unit and transfers them to an alert generation module. This processing method expands a closed-system simulation model and handles a dynamic change in a boundary condition in an open system. Thereby, the system calculates a macro ripple effect crossing a boundary of a city from an interaction of micro agents. The system exhibits a technical effect of improving prediction accuracy for a sudden load fluctuation due to an external factor. As a specific application field, a wide-area evacuation simulation task at the time of a large-scale disaster requiring wide-area cooperation can be cited.

As described above, the embodiment of the present invention provides an extremely practical and highly scalable system capable of modeling all members involved in city management in detail as virtual agents, analyzing and learning various data inside and outside the city using generative AI, highly accurately and dynamically realizing a simulation of a city policy or a policy proposal, and enabling a city manager or a policymaker to scientifically grasp multilateral influences, risks, and ripple effects before implementation of a policy, and to draft optimal city management, consensus building, and a risk reduction policy. Specifically, this system executes a hybrid arithmetic architecture integrating agent-based modeling and deep learning. This system containerizes each functional unit and dynamically allocates computational resources using an orchestration tool. Input data to this system is a composite tensor of static infrastructure data of the city, dynamic sensor data, and virtual policy parameters. As a specific example of the input data, a multidimensional array combining 3D city model data of the city and real-time weather data can be cited. As another specific example of the input data, batch data of condition vectors encoding a plurality of policy options can be cited. This system inputs these input data into a parallel processing pipeline and executes a large-scale inference operation. This system outputs multilateral evaluation metrics for each policy option. As a specific example of the output data, a numerical array for a radar chart indicating predicted values of an economic effect, an environmental load, and a resident satisfaction level for each policy can be cited. As another specific example of the output data, a solution vector of an optimization algorithm proposing a combination of policies with the lowest risk can be cited. This system integrally displays these output data on a decision-making support dashboard. This processing method completely replaces a conventional city planning process depending on human rules of thumb with a data-driven and computer-scientific approach. Thereby, this system derives a mathematically supported optimal solution for a city problem in which an enormous number of variables are intertwined. This system exerts a technical effect of significantly shortening a lead time of policy drafting and dramatically enhancing resilience of city management. As a specific application field, a master plan formulation task of a next-generation smart city in a national strategic special zone can be cited.

### System Configuration

The system according to the present embodiment comprises an agent generation unit, a data analysis unit, a simulation execution unit, a user interface unit, a database unit, and an AI learning management unit. The agent generation unit has a function of modeling various subjects constituting the city as virtual agents, and can assign various attribute information related to city life, such as age, gender, place of residence, family structure, health condition, commuting means, owned vehicle, environmental awareness, motivation, satisfaction level, SNS use frequency, purchasing tendency, degree of participation in a local community, evacuation tendency at the time of a disaster, past event participation history, administrative service use history, hobby/interest field, presence or absence of a pet, type of housing, remote work implementation status, and child-rearing status, to a resident agent, for example, and can generate an agent having detailed attributes such as a 35-year-old male living in Kita Ward, living with a spouse and two children, commuting by bicycle, having high environmental awareness, frequently transmitting local information on SNS, having experience of participating in a disaster drill and a local cleaning activity in the past, having an item requiring observation in a health checkup, keeping a dog as a pet, living in a condominium, and implementing remote work twice a week, for example. Further, the agent generation unit assigns an affiliated department, a task in charge, years of service, a policy orientation, a past policy track record, a frequency of contact with residents, a working style, a response experience at the time of a disaster, an administrative evaluation score, a training attendance history, a transfer history, and the like as attributes to an administrative staff agent, and assigns a store scale, an industry type, the number of employees, a sales transition, a sponsorship history for a local event, a participation status in an environmental policy, business hours, a location characteristic, a trade area population, a point card introduction status, presence or absence of an SNS sales promotion activity, a business continuity plan at the time of a disaster, a commuting means of an employee, a tenant contract form, and the like to a commercial facility operator agent. The agent generation unit assigns a place of origin, a purpose of stay, a period of stay, an accommodation facility, a moving means, a sightseeing spot visit history, an information collection means, a consumption tendency, an accompanying person attribute, a past city visit experience, an evacuation behavior tendency at the time of a disaster, and the like as attributes to a tourist or temporary stayer agent, and sets an affiliated organization, a specialized field, a dispatch experience, a stayable period, a cooperation destination institution, a past disaster response track record, a type of equipment/materials, a local arrival means, an information communication means, and the like in detail for a support personnel agent at the time of a disaster. Specifically, this system is configured as a distributed computing system in which each functional unit is connected by a high-speed internal bus or a broadband network. The agent generation unit samples an attribute value of an agent using a random number generator and a probability distribution model. The agent generation unit normalizes the sampled value and generates a fixed-length attribute vector. Input data to this system is a CSV file including census data and aggregation results of various statistical surveys. As a specific example of the input data, histogram data indicating a population distribution by age in Kita Ward can be cited. As another specific example of the input data, an aggregation table of categorical data indicating the number of stores by industry type of commercial facilities can be cited. The agent generation unit generates individual agent data while maintaining statistical properties based on these input data. The agent generation unit outputs an attribute matrix of the generated agent group. As a specific example of the output data, a floating-point matrix of 1 million rows and 256 columns storing attributes of 1 million resident agents can be cited. As another specific example of the output data, tensor data of 50,000 rows and 128 columns storing attributes of 50,000 commercial facility agents can be cited. This system loads this attribute matrix into an in-memory database and speeds up subsequent simulation processing. This processing method executes an algorithm for inversely generating micro individual data from macro statistical data. Thereby, this system constructs a virtual environment accurately reflecting an actual city structure even when raw data cannot be used from the viewpoint of personal information protection. This system exerts a technical effect of efficiently setting up initial conditions for a large-scale simulation while ensuring data privacy. As a specific application field, a digital twin construction task of a local government under a personal information protection legal system can be cited.

The data analysis unit has a function of collecting information from various data sources inside and outside the city and analyzing the information using generative AI, and collects, for example, a traffic volume sensor, an environmental sensor, a disaster prevention sensor, a congestion degree sensor, an energy consumption sensor, a garbage discharge amount sensor, and the like as various sensor data in the city, and collects a policy implementation history, a resident questionnaire, an administrative procedure history, a complaint/request record, local meeting minutes, an administrative evaluation report, a disaster response record, a public facility use history, a subsidy application history, city planning materials, and the like as administrative records. The data analysis unit collects a local community posting, an event announcement, information diffusion at the time of a disaster, word of mouth, transmission from an administrative official account, resident opinion expression, a tourist experience posting, a commercial facility sales promotion posting, transportation operation information, volunteer recruitment information, and the like as SNS postings, integrates a public transportation use history, road congestion data, a parking lot use history, a shared bicycle use history, a taxi dispatch history, a traffic accident occurrence record, a school route use status, and the like as traffic history, collects purchasing data, a point card use history, an event participation history, a campaign reaction, a sales transition, a visitor attribute, trade area analysis data, an electronic payment use history, commercial facility congestion degree data, and the like as commercial activity history, collects an evacuation shelter use history, a relief supply distribution history, an evacuation behavior log, a damage situation report, a disaster volunteer activity record, a communication failure occurrence history at the time of a disaster, a contact history between an administration and a resident, and the like as disaster response records, and utilizes a tourist satisfaction survey, an event participant questionnaire, a city brand survey, a prospective immigrant questionnaire, a foreign tourist awareness survey, a transportation user questionnaire, and the like as external questionnaire results. The generative AI analyzes these massive amounts of data by methods such as natural language processing, time-series analysis, sentiment analysis, clustering, network analysis, anomaly detection, and pattern mining, extracts opinion tendencies, emotional tendencies, influence relationships, information propagation routes, and behavior patterns by role, by region, and by individual, such as “residents in Kita Ward have a strong interest in expanding bicycle infrastructure”, “commercial facility operators in Minami Ward are positive about holding a large-scale event”, “administrative staff in Chuo Ward feel a problem in information transmission at the time of a disaster”, “tourists emphasize information collection on SNS”, “the elderly strongly request an improvement in convenience of public transportation”, “the youth have a high motivation to participate in an event”, and “foreign tourists emphasize multilingual guidance display”, for example, also analyzes changes in chronological order, a satisfaction level/motivation change after implementation of a specific policy, an increase in a defection risk, a speed and range of information diffusion, a real-time change in an evacuation behavior at the time of a disaster, an occurrence timing of traffic congestion at the time of holding an event, and the like, and dynamically updates agent attributes and a state of the entire city. Specifically, the data analysis unit processes data flowing in in real time using a stream processing engine. The data analysis unit executes a multi-task learning model integrating natural language processing, time-series analysis, and a graph neural network. Input data to the multi-task learning model is a multimodal tensor of time-series numerical data of a sensor and text data. As a specific example of the input data, a multidimensional time-series array of an environmental sensor sampled at 1-minute intervals can be cited. As another specific example of the input data, a word embedding vector of text extracted from a complaint record to the administration can be cited. The multi-task learning model extracts a common feature representation from these input data using a shared hidden layer. The multi-task learning model simultaneously outputs a plurality of prediction results via a task-specific output layer. As a specific example of the output data, a continuous value score from 0 to 1 indicating a dissatisfaction degree of residents in each region can be cited. As another specific example of the output data, adjacency matrix data of a directed graph indicating an information propagation route on SNS can be cited. The data analysis unit updates a state vector of an agent in real time using these output results. This system executes an anomaly detection algorithm, and immediately fires an alert signal when detecting a rapid state change. This processing method integrates a plurality of independent analysis models and realizes sharing of computational resources and generalization of a feature representation. Thereby, this system improves analysis accuracy as compared with a single-task model, and reduces a calculation cost required for inference. This system exerts a technical effect of grasping dynamics of the city without delay and maximizing a throughput of a data processing pipeline. As a specific application field, a real-time situation grasping and anomaly detection task in an integrated monitoring center of a city can be cited.

The simulation execution unit has a function of receiving a virtual policy proposal such as a city policy, an infrastructure policy, a traffic regulation, a disaster countermeasure, and an event holding as an input, and predicting what kind of reaction or behavior each agent shows to the policy proposal using generative AI, and when a “bicycle-dedicated road expansion” policy is input, for example, various reactions are obtained by role and by attribute, such that bicycle commuters and a group with high environmental awareness among resident agents actively approve, car commuters and commercial facility operators oppose, administrative staff are neutral or approve, traffic managers approve or propose, and tourists pay attention as a new tourism resource. The AI simultaneously simulates a motivation or satisfaction level change, a defection risk, an additional proposal, an information diffusion behavior, and a moving behavior of each agent, and various behaviors are simulated, such that in a “large-scale event holding” policy, commercial facility operators and traffic managers approve or actively participate, some residents oppose due to congestion or noise, tourists actively participate, and administrative staff approve while being concerned about an increase in an operation burden, and in a disaster countermeasure policy, evacuation shelter operators and medical workers actively respond, residents take an evacuation behavior or an information collection behavior, traffic managers take a traffic regulation or a guidance behavior, tourists are confused due to lack of information or diffuse information on SNS, and support personnel at the time of a disaster take a cooperation behavior after arriving at a site. Furthermore, the AI also considers a combination of policies and a change in chronological order, and can highly accurately predict an influence due to an interaction of a plurality of policies, such as “when a public transportation discount policy is implemented simultaneously with bicycle-dedicated road expansion”, “when an event holding and a traffic regulation are implemented simultaneously”, and “when evacuation shelter expansion and information transmission enhancement are performed simultaneously at the time of a disaster”, for example. Specifically, the simulation execution unit comprises a composite artificial intelligence architecture combining a large language model and a graph neural network. The simulation execution unit analyzes a natural language text of the input policy proposal by a natural language processing module. The natural language processing module tokenizes the text. The natural language processing module converts a token sequence into a multidimensional word embedding vector. The simulation execution unit generates a feature amount vector obtained by digitizing attribute information of each agent. The feature amount vector is, for example, a 1024-dimensional floating-point number array. Categorical variables such as age and gender are one-hot encoded and stored in the feature amount vector. The simulation execution unit combines the embedding vector of the policy proposal and the feature amount vector of the agent. The simulation execution unit inputs the combined tensor into the large language model. The large language model extracts a feature of the input tensor using a self-attention mechanism. The large language model outputs a reaction probability distribution vector of each agent. The reaction probability distribution vector includes a probability value for each category such as approval, neutrality, and opposition. For example, a numerical group such as an approval probability of 0.85 and an opposition probability of 0.05 is output. The large language model simultaneously outputs a motivation change amount. The motivation change amount is expressed as a continuous value from minus 1.0 to plus 1.0. The simulation execution unit executes a threshold determination process on the output probability distribution vector. The simulation execution unit determines a category having a maximum probability as a final behavior label of the agent. The simulation execution unit inputs the determined behavior label into a subsequent graph neural network. The graph neural network holds an adjacency matrix expressing a social network structure among agents. The graph neural network calculates a ripple effect of information diffusion or an interaction using the adjacency matrix. This system executes these nonlinear operations in a high-dimensional space in parallel using a graphics processing unit. By this processing, this system exerts a technical effect of being able to calculate a complex interaction of a plurality of policies with accuracy and speed impossible by conventional manual rule-based prediction. This technology is extremely useful in a specific application field such as prior verification of a traffic infrastructure development plan or a security plan for a large-scale event in a smart city.

The user interface unit has a function of visualizing a simulation result from various perspectives such as by role, by region, by individual, in chronological order, and by network, and can display “which region approves or opposes” by color coding in a heat map, display “a motivation or satisfaction level change” in chronological order in a bar graph, visualize “an information propagation route or an influence relationship” in a network diagram, and indicate “a reaction transition after implementation of a policy” in a timeline display, for example. A user can adjust parameters of a policy proposal (e.g., a target region, a policy scale, budget allocation, a traffic regulation range, an event holding schedule, disaster countermeasure contents, a subsidy amount, an information transmission means, the number of evacuation shelters, a medical system enhancement policy, etc.), re-execute a simulation in real time, and compare and examine a plurality of scenarios. Furthermore, the user interface unit also comprises a function of exporting a simulation result in a PDF, image, or table format, a function of searching and re-displaying a past simulation history, an automatic report generation function by AI, a point extraction function for a decision maker, a risk alert notification function, and the like. Specifically, the user interface unit comprises an advanced parallel rendering engine using a graphics processing unit. The user interface unit receives multidimensional tensor data output from the simulation execution unit. The user interface unit converts the received tensor data into two-dimensional pixel array data. The user interface unit executes a heat map generation algorithm. This algorithm calculates a spatial data concentration degree using kernel density estimation. The user interface unit determines a color difference signal of each pixel based on a calculation result. The user interface unit executes a dynamic model layout algorithm for drawing a network diagram. This algorithm iteratively calculates an attractive force and a repulsive force between nodes. This algorithm determines optimal two-dimensional coordinates of each node. The user interface unit detects a parameter change operation from a user. The user interface unit extracts only difference data of the changed parameter. The user interface unit transmits the difference data to the simulation execution unit. The simulation execution unit executes recalculation targeting only an agent affected based on the difference data. The user interface unit receives a recalculated result by asynchronous communication. The user interface unit partially redraws only a corresponding area of a screen. By this difference update processing, this system significantly reduces a communication bandwidth between a server and a terminal. At the same time, this system reduces a processing load of an arithmetic node. Thereby, this system exerts a technical effect of being able to update a screen in real time without delay even for large-scale data handling millions of agents. This technology is utilized in a specific application field such as visualization of a real-time evacuation situation in a disaster countermeasure headquarters or interactive consensus building support in a resident briefing session for city planning.

The database unit has a function of centrally managing agent data, city data, communication history, simulation history, policy proposal history, AI learning data, track record data, external cooperation data, and the like, accumulates, for example, a past simulation result, a resident satisfaction survey result after actual implementation of a policy, the number of event participants, a traffic volume change, an evacuation behavior log at the time of a disaster, a topic diffusion history on SNS, a sales transition of a commercial facility, an administrative evaluation report, and the like, and improves simulation accuracy by the AI continuously learning. Specifically, the database unit adopts a hybrid storage architecture combining a distributed relational database and a graph database. The database unit stores static attribute data of an agent in a table of the relational database. The database unit stores a relationship among agents and an information propagation route as a node and an edge of the graph database. The database unit executes a sharding process of dividing and arranging input large-scale data into a plurality of physical servers. The database unit calculates a unique hash value for each data record. The database unit determines a storage destination node of data based on the hash value. The database unit expands frequently accessed data into an in-memory cache. The database unit comprises a dedicated data pipeline for continuous learning of artificial intelligence. This data pipeline periodically batch-processes accumulated track record data and simulation history. This data pipeline normalizes text data and log data. This data pipeline converts the normalized data into a multidimensional tensor for learning. The database unit saves the converted tensor data in a storage area for learning. By this hybrid configuration and distributed processing, this system dramatically improves a search speed of large-scale data having a complex relationship. Furthermore, this system eliminates an input/output bottleneck in reading and writing data. Thereby, this system brings about a technical effect of being able to speed up a learning cycle of an artificial intelligence model and continuously improve simulation accuracy. This technology becomes an indispensable foundation in a specific application field such as a high-speed search for a correlation between a past city policy history and a resident reaction, or accumulation and analysis of real-time sensor data.

The AI learning management unit is responsible for management of an AI learning data set, creation of teacher data, construction of a feedback loop, version management of an AI model, external AI cooperation, update of an anomaly detection model, parameter optimization, automatic scenario generation, and the like, and enables operations such as “causing AI to learn track record data after past implementation of a policy to improve future simulation accuracy”, “causing AI to learn an actual evacuation behavior log at the time of a disaster to enhance accuracy of evacuation behavior prediction”, and “causing AI to learn a topic diffusion history on SNS to improve accuracy of information propagation prediction”, for example. Specifically, the AI learning management unit comprises a dedicated arithmetic module for executing algorithms of reinforcement learning and self-supervised learning. The AI learning management unit acquires multidimensional tensor data for learning from the database unit. The AI learning management unit divides the acquired data into training data and verification data. The AI learning management unit executes a forward propagation process of an artificial intelligence model. The AI learning management unit calculates an error between an output value of the model and actual observation data. A composite loss function combining a cross-entropy error function and a mean square error function is used for this error calculation. The AI learning management unit executes a gradient descent method based on the calculated error. The AI learning management unit updates a weight parameter of each node in a network by backpropagation. The AI learning management unit operates an autoencoder network as an anomaly detection model. This autoencoder network compresses input data into a low-dimensional latent space. This autoencoder network reconstructs an original input from the compressed data. The AI learning management unit calculates a reconstruction error which is a difference between the input data and the reconstructed data. The AI learning management unit detects data whose reconstruction error exceeds a predetermined threshold as an unknown pattern. The AI learning management unit executes an automatic search algorithm for a hyperparameter. This algorithm searches for an optimal combination of a learning rate, a batch size, and the like using Bayesian optimization. By this continuous weight update and parameter optimization, this system autonomously adapts to a change over time in an environment. Thereby, this system exerts a technical effect of being able to maintain and improve inference accuracy without human intervention. This technology is extremely effective in a specific application field such as following a new social media trend change or automatic adaptation of a prediction model to an unknown meteorological disaster pattern.

As specific examples of a prompt sentence to be read by generative AI necessary when implementing the present invention, “Based on the following city member data and city policy proposal, classify what kind of reaction or behavior each agent shows into categories such as approval, neutrality, opposition, defection, proposal, information diffusion, movement, participation, and withdrawal, and output it together with a reason”, “Analyze past SNS postings and traffic history, and extract in which region congestion or information diffusion is likely to occur at the time of holding an event”, “With a disaster countermeasure policy as an input, predict an evacuation behavior or an information collection behavior of a resident, an administrative staff member, support personnel, and a tourist in chronological order, and output it numerically by region and by attribute”, “Generate a data set for graphing a simulation result by role, by region, and in chronological order”, “Visualize an influence due to an interaction when a plurality of policies are implemented simultaneously as a satisfaction level, motivation, a risk, and a ripple effect”, and the like can be cited. Specifically, this system comprises a dedicated prompt generation module for dynamically generating a prompt. The prompt generation module holds a plurality of predefined prompt templates in a memory. The prompt generation module extracts an attribute vector of a target agent or a time-series array of city data from the database unit. The prompt generation module inversely converts the extracted numerical data into a natural language text character string. The prompt generation module embeds the inversely converted character string into a variable part of the template. The prompt generation module inputs the generated prompt character string into a large language model. The large language model analyzes the input prompt. The large language model generates an output text in accordance with a designated format. This output text is composed of a hierarchical data format consisting of a key-value pair. For example, the output text includes an agent identifier, a reaction category, a certainty score, and a reason text. This system comprises a syntax analyzer. The syntax analyzer parses the text output from the large language model. The syntax analyzer extracts numerical data such as a certainty score from the text. This system transfers the extracted numerical data to a subsequent aggregation processing module. By this structuring and dynamic generation processing of a prompt, this system strictly suppresses a fluctuation or a format violation of an output from the large language model. Thereby, this system exerts a technical effect of being able to link a natural language processing result as reliable structured data to subsequent system processing. This technology plays an important role in a specific application field such as automatic extraction of a quantitative evaluation metric for various city policies or automatic construction of a knowledge graph from unstructured data.

As described above, the system according to the present embodiment comprises an agent generation unit, a data analysis unit, a simulation execution unit, a user interface unit, a database unit, and an AI learning management unit, models all members involved in city management and an inflow person outside the city in detail as virtual agents, analyzes and learns various data inside and outside the city using generative AI, highly accurately and dynamically realizes a simulation of a city policy or a policy proposal, and provides an extremely practical and highly scalable system enabling a city manager or a policymaker to scientifically grasp multilateral influences, risks, and ripple effects before implementation of a policy, and to draft optimal city management, consensus building, and a risk reduction policy. Specifically, this system adopts a distributed computing architecture operating on a parallel arithmetic cluster composed of a plurality of arithmetic nodes. The agent generation unit, the data analysis unit, the simulation execution unit, the user interface unit, the database unit, and the AI learning management unit, which are respective components of this system, are implemented as independent microservices. Each unit asynchronously communicates via a message queuing system. This system integrates a series of processes from generation of an agent to analysis of data, execution of a simulation, and visualization of a result as a data pipeline. This system passes multidimensional tensor data between respective processing steps. This system utilizes hardware acceleration of a matrix operation using a graphics processing unit. This system maximizes a cache hit rate by arranging data in a continuous area on a memory. By this loosely coupled module configuration and data processing optimized for hardware, this system can prevent a stop of the entire system even when a failure occurs in a specific node. Furthermore, this system ensures scalability to dynamically add or delete an arithmetic node in accordance with a processing load. Thereby, this system brings about a technical effect of being able to stably and rapidly execute a city-scale simulation requiring enormous computational resources. This technology demonstrates its true value in a specific application field such as construction of a comprehensive city planning simulation platform in a megacity having a population of millions of scale, or a foundation of a wide-area disaster countermeasure system at a national level.

### Implementation Steps

### Step 1: Generation of City Member Agents

Various subjects constituting a city, such as residents, administrative staff, commercial facility operators, traffic managers, tourists, and support personnel at the time of a disaster, are generated as virtual agents, and various attribute information related to city life and city management, such as age, gender, place of residence, family structure, health condition, commuting means, owned vehicle, environmental awareness, motivation, satisfaction level, SNS use frequency, purchasing tendency, local community participation degree, evacuation tendency at the time of a disaster, event participation history, administrative service use history, hobby/interest field, presence/absence of a pet, housing type, remote work implementation status, child-rearing status, affiliated department, assigned task, years of service, policy orientation, store scale, industry type, number of employees, sales transition, sponsorship history, purpose of stay, period of stay, accommodation facility, moving means, tourist spot visit history, information collection means, consumption tendency, accompanying person attribute, dispatch experience, type of equipment/materials, local arrival means, and information communication means, is assigned to each agent. Specifically, the agent generation unit executes an initialization process when the system is started. The agent generation unit performs an assignment process of an attribute value based on a statistical probability distribution using a random number generator. The agent generation unit expands each agent as a multidimensional feature vector on a main memory. The feature vector is defined as, for example, a 256-dimensional floating-point number array. The agent generation unit normalizes continuous variables such as age and income and stores them in specific elements in the vector. The agent generation unit converts categorical variables such as gender and occupation into binary values by a one-hot encoding method. The agent generation unit stores the converted binary values in the remaining elements of the vector. The agent generation unit combines millions of generated feature vectors into a matrix format. The agent generation unit transfers the combined huge matrix data to a video memory of a graphics processing unit. By this vector arrangement and matrixing in a continuous area on the memory, the system maximizes parallel processing efficiency of tensor operations in a subsequent artificial intelligence model. Thereby, the system exhibits a technical effect of reducing a memory access overhead and dramatically improving a processing speed of agent generation and initialization. This technology is an essential process in specific application fields such as construction of a precise digital twin city based on census data and various statistical data, and initial state setting of a large-scale consumer behavior simulation.

### Step 2: Collection and Integration of City Data

From various data sources inside and outside the city, traffic volume sensors, environmental sensors, disaster prevention sensors, congestion degree sensors, energy consumption sensors, garbage discharge amount sensors, policy implementation history, resident questionnaires, administrative procedure history, complaint/request records, local meeting minutes, administrative evaluation reports, disaster response records, public facility use history, subsidy application history, city planning materials, local community postings, event announcements, information diffusion at the time of a disaster, word-of-mouth, administrative official transmissions, resident opinion expressions, tourist experience postings, commercial facility sales promotion postings, transportation operation information, volunteer recruitment information, public transportation use history, road congestion data, parking lot use history, share cycle use history, taxi dispatch history, traffic accident occurrence records, school route use status, purchasing data, point card use history, event participation history, campaign reactions, sales transitions, visitor attributes, trade area analysis data, electronic payment use history, commercial facility congestion degree data, evacuation shelter use history, relief supply distribution history, evacuation behavior logs, damage situation reports, disaster volunteer activity records, communication failure occurrence history, communication history between administration and residents, tourist satisfaction surveys, event participant questionnaires, city brand surveys, prospective immigrant questionnaires, foreign tourist awareness surveys, transportation user questionnaires, and the like are collected and integrated. Specifically, the data collection unit establishes an asynchronous communication interface with various sensor groups and an external data provision system. The data collection unit receives stream data through a network. The data collection unit executes real-time preprocessing on the received data. In the preprocessing, the data collection unit complements missing values using a linear interpolation algorithm. The data collection unit smoothes or removes statistical outliers using a moving average method. The data collection unit synchronizes time stamps of data acquired from different sources in milliseconds based on a network time protocol. The data collection unit temporarily stores the preprocessed data in a buffer memory as time-series array data. The data collection unit utilizes edge computing technology. The system executes primary aggregation processing of data on an edge device arranged on the sensor side. The edge device converts raw data into a feature vector and then transmits it to a central server. By this distributed processing architecture, the system significantly reduces consumption of a communication bandwidth to the central server. At the same time, the system reduces a data parsing load of the central server. Thereby, the system exhibits a technical effect of being able to integrate a huge variety of city data without delay and always maintain the latest city state. This technology functions extremely effectively in specific application fields such as probe data collection for real-time traffic congestion prediction and instantaneous monitoring of power consumption data in a smart grid.

### Step 3: Analysis of City Data and Extraction of Agent Attributes and Tendencies (Utilization of Generative AI)

Using generative AI, the collected city data is analyzed by methods such as natural language processing, time-series analysis, sentiment analysis, clustering, network analysis, anomaly detection, and pattern mining, and opinion tendencies, emotional tendencies, influence relationships, information propagation routes, and behavior patterns by role, by region, and by individual, such as “residents in Kita Ward have a strong interest in expanding bicycle infrastructure”, “commercial facility operators in Minami Ward are positive about holding large-scale events”, “administrative staff in Chuo Ward feel a problem in information transmission at the time of a disaster”, “tourists emphasize information collection on SNS”, “the elderly strongly request improvement in convenience of public transportation”, “the youth have a high motivation to participate in events”, and “foreign tourists emphasize multilingual guide displays”, are extracted, and changes in chronological order, satisfaction level/motivation changes after implementation of a specific policy, an increase in defection risk, a speed and range of information diffusion, real-time changes in evacuation behavior at the time of a disaster, occurrence timing of traffic congestion at the time of holding an event, and the like are also analyzed, and agent attributes and the state of the entire city are dynamically updated. Specific examples of prompt sentences to be read by the generative AI include “Analyze the following city data, extract attributes, opinion tendencies, emotional tendencies, influence relationships, and behavior patterns of each agent, and quantify them by role, by region, and by individual”,

“Analyze past SNS postings and traffic history, and extract in which region congestion and information diffusion are likely to occur when an event is held”, and the like. Specifically, the data analysis unit simultaneously executes a natural language processing model and a time-series analysis model on a parallel computing cluster. The natural language processing model adopts a transformer architecture equipped with a self-attention mechanism. The data analysis unit converts the collected text data into a word embedding matrix. The data analysis unit inputs the word embedding matrix to the natural language processing model. The natural language processing model calculates dependency relationships between words in the text. The natural language processing model outputs an emotion score of each agent. The emotion score is expressed as a floating-point number from minus 1.0 to plus 1.0. The natural language processing model simultaneously outputs a topic classification label. The data analysis unit executes a long short-term memory network as the time-series analysis model. The time-series analysis model receives a time-series tensor of past behavior history as an input. The time-series analysis model outputs a future behavior probability. The data analysis unit dynamically updates the agent feature vector on the memory using the extracted emotion score and behavior probability. By this combination of the self-attention mechanism and the time-series analysis, the system accurately captures long-term dependency of context and patterns of temporal changes. Thereby, the system brings about a technical effect of realizing highly accurate emotion extraction and tendency analysis that are impossible with simple keyword matching or statistical processing. This technology becomes a powerful tool in specific application fields such as a system for predicting a future protest activity occurrence risk from accumulation of minute dissatisfaction on social media, and marketing analysis for capturing minute changes in consumers' purchasing motivation.

### Step 4: Input of City Policy Proposal and Setting of Simulation Conditions

A user inputs a virtual policy proposal such as a city policy, an infrastructure policy, a traffic regulation, a disaster countermeasure, and an event holding, and sets simulation conditions such as a target region, a policy scale, budget allocation, a traffic regulation range, an event holding schedule, disaster countermeasure contents, a subsidy amount, an information transmission means, the number of evacuation shelters, and a medical system strengthening measure in detail. Specifically, the policy input unit receives an input signal from a user terminal via a secure communication protocol. The policy input unit executes strict type checking and range verification on the received input parameter group. The policy input unit confirms, for example, that the budget allocation is a positive integer and that coordinate data of the target region is within a valid range. The policy input unit normalizes the parameter group that has passed the verification. The policy input unit converts the normalized data into a hash map structure consisting of key-value pairs. The policy input unit serializes the hash map as a setting file for simulation. The policy input unit expands the serialized data on a memory in a binary format. The policy input unit transmits a setting completion signal to the simulation execution unit. By this strict input verification and data structuring process, the system prevents abnormal termination and infinite loops during simulation execution due to invalid values or inconsistent parameters. Thereby, the system exhibits a technical effect of enhancing robustness of software and guaranteeing stable operation of the entire system. This technology is an indispensable function in specific application fields such as rapid setting of a scenario in which a plurality of policy options are complexly combined, and execution of thousands of parameter sweep tests by automated batch processing.

### Step 5: Execution of City Policy Simulation by Generative AI

Using generative AI, what kind of reaction or behavior each agent shows to the policy proposal is predicted, reactions and behaviors such as approval, neutrality, opposition, defection, proposal, information diffusion, movement, participation, and withdrawal are diversely calculated by role and by attribute, and a motivation or satisfaction level change, a defection risk, an additional proposal, an information diffusion behavior, and a moving behavior are also simultaneously simulated. Specific examples of prompt sentences to be read by the generative AI include “Based on the following city member data and city policy proposal, classify what kind of reaction or behavior each agent shows into categories such as approval, neutrality, opposition, defection, proposal, information diffusion, movement, participation, and withdrawal, and output them together with reasons”, “With a disaster countermeasure policy as an input, predict evacuation behaviors and information collection behaviors of residents, administrative staff, support personnel, and tourists in chronological order, and output them numerically by region and by attribute”, and the like. Specifically, the simulation execution unit executes an inference process using a large language model on a graphics processing unit. The simulation execution unit combines the feature vector of the agent and an embedding vector of the policy proposal. The simulation execution unit constructs the combined data as a multidimensional input tensor. The simulation execution unit supplies the input tensor to an input layer of the large language model. The large language model performs feature transformation through a multi-layer neural network. An output layer of the large language model applies a softmax function. The large language model outputs a probability distribution vector for each behavior category. For example, as output data, a numerical group such as an approval probability of 0.75, an opposition probability of 0.15, and a neutrality probability of 0.10 is generated. The simulation execution unit extracts a category having the maximum probability from the output probability distribution vector. The simulation execution unit adopts the extracted category as a behavior label of the agent. The simulation execution unit inputs the behavior label to a state transition model and updates an internal state variable of the agent. By this hardware acceleration of tensor operations, the system completes a huge calculation task of reaction prediction of millions of agents within a practical time. Thereby, the system exhibits a technical effect of being able to simulate emergence of a macro city phenomenon due to accumulation of micro individual decision-making, which was impossible with conventional methods. This technology provides extremely high value in specific application fields such as prediction of a compliance rate of residents with a lockdown policy at the time of a pandemic occurrence, and prediction of changes in economic behavior at the time of introduction of a new tax system.

### Step 6: Aggregation, Visualization, and Comparison of Simulation Results

The simulation execution unit and the user interface unit visualize the simulation results from various perspectives such as by role, by region, by individual, in chronological order, and by network using a heat map, a bar graph, a network diagram, a timeline display, and the like, and the user can adjust parameters of the policy proposal, re-execute the simulation in real time, and compare and examine a plurality of scenarios. Specifically, an aggregation processing module in the simulation execution unit aggregates the output behavior labels and state variables. The aggregation processing module executes a distributed aggregation process using a MapReduce algorithm. The aggregation processing module performs partial aggregation at each computing node and integrates the results at a central node. The user interface unit receives the integrated aggregation result. The user interface unit converts the aggregation result into a graph data structure consisting of vertices and edges. The user interface unit executes a layout algorithm using a dynamic model and calculates two-dimensional coordinates of each vertex on a screen. The user interface unit draws a network diagram or a heat map in a rendering buffer based on the calculated coordinates. The user interface unit outputs the drawn image data to a display of the user terminal. By this distributed aggregation algorithm and efficient drawing process, the system eliminates a processing bottleneck of large-scale data. Thereby, the system brings about a technical effect of dramatically shortening a response time to the user and providing immediate visual feedback to parameter changes. This technology is indispensable in specific application fields such as provision of an interactive dashboard for comparing effects of a plurality of traffic regulation patterns side by side, and a disaster response simulator requiring real-time decision-making.

### Step 7: Accumulation of Simulation Results and City Data, and AI Learning Feedback

The database unit centrally manages agent data, city data, communication history, simulation history, policy proposal history, AI learning data, performance data, external cooperation data, and the like, and the AI learning management unit causes the AI to learn performance data after past policy implementation, evacuation behavior logs at the time of a disaster, topic diffusion history on SNS, and the like, and continuously improves future simulation accuracy and prediction accuracy. Specific examples of prompt sentences to be read by the generative AI include “Cause the AI to learn performance data after past policy implementation to improve future simulation accuracy”, “Cause the AI to learn actual evacuation behavior logs at the time of a disaster to enhance accuracy of evacuation behavior prediction”, and the like. Specifically, the database unit writes the aggregated simulation results into a time-series database. The time-series database has a structure of appending data at high speed using a time stamp as a primary key. The AI learning management unit periodically activates a learning feedback pipeline. The AI learning management unit acquires past prediction data and actual observation data from the time-series database. The AI learning management unit calculates a difference between the two and generates an error vector. The AI learning management unit calculates a norm of the error vector. When the calculated norm exceeds a predetermined threshold, the AI learning management unit automatically starts a re-learning process. In the re-learning process, the AI learning management unit updates weight parameters of a neural network by a gradient descent method so as to minimize the error. By this autonomous feedback loop, the system detects accuracy degradation of the model without human intervention and automatically performs correction. Thereby, the system exhibits a technical effect of being able to always maintain high prediction accuracy adapted to the latest environmental changes while significantly reducing operation and maintenance costs. This technology is extremely important in specific application fields such as operation of a city simulator that automatically follows seasonal fluctuations and long-term demographic changes, and updating of a threat prediction model for continuously changing cyber attacks.

### Specific Use Case

For example, when a city operator considers introduction of a “bicycle-dedicated road expansion” policy, first, the agent generation unit generates various members such as city residents, administrative staff, commercial facility operators, traffic managers, and tourists as virtual agents, and assigns detailed attributes such as age, gender, place of residence, family structure, health condition, commuting means, owned vehicle, environmental awareness, motivation, satisfaction level, SNS use frequency, purchasing tendency, local community participation degree, evacuation tendency at the time of a disaster, event participation history, administrative service use history, hobby/interest field, housing type, remote work implementation status, and child-rearing status to each agent. Next, the data analysis unit collects various data inside and outside the city, such as traffic volume sensors, environmental sensors, SNS postings, administrative questionnaires, sales data of commercial facilities, public transportation use history, opinion postings of local communities, event participation history, and evacuation behavior logs at the time of a disaster, extracts opinion tendencies, emotional tendencies, influence relationships, information propagation routes, and behavior patterns by role, by region, and by individual, such as “residents in Kita Ward have a strong interest in expanding bicycle infrastructure”, “commercial facility operators in Minami Ward are concerned about a decrease in customers due to road expansion”, “the elderly request improvement in safety of sidewalks”, “bicycle commuters are actively approving”, and “car commuters are opposed to a decrease in parking lots” using generative AI, and dynamically updates agent attributes and the state of the entire city. When the city operator inputs a “bicycle-dedicated road expansion” policy proposal and sets simulation conditions such as a target region, a road width, a budget, a traffic regulation range, a subsidy amount, and an information transmission means in detail, the simulation execution unit predicts reactions and behaviors of each agent using the generative AI, diversely calculates reactions and behaviors such as approval, neutrality, opposition, defection, proposal, information diffusion, movement, participation, and withdrawal by role and by attribute, and simultaneously simulates a motivation or satisfaction level change, a defection risk, an additional proposal, an information diffusion behavior, and a moving behavior. For example, results such as “bicycle commuters in Kita Ward are actively approving”, “commercial facility operators in Minami Ward are strongly opposed”, “the elderly additionally propose sidewalk widening”, “pros and cons diffuse on SNS”, and “some residents consider shifting to alternative transportation means” are obtained. The user interface unit visualizes these simulation results by region, by role, in chronological order, and by network using a heat map, a bar graph, a network diagram, a timeline display, and the like, and the city operator can compare and examine a plurality of scenarios while changing parameters of the policy proposal. The database unit centrally manages agent data, city data, simulation history, and performance data, and the AI learning management unit causes the AI to learn performance data after past policy implementation, SNS diffusion history, evacuation behavior logs, and the like to improve future simulation accuracy. Specific examples of prompt sentences to be read by the generative AI include “Based on the following city member data and bicycle-dedicated road expansion policy proposal, classify what kind of reaction or behavior each agent shows into categories such as approval, neutrality, opposition, defection, proposal, information diffusion, movement, participation, and withdrawal, and output them together with reasons”, “Analyze past SNS postings and traffic history, and extract in which region congestion and information diffusion are likely to occur when the road expansion policy is implemented”, “Generate a dataset for graphing simulation results by region, by role, and in chronological order”, and the like. In this way, by using the system of the present invention, reactions, ripple effects, and risks of various members can be scientifically and multilaterally predicted and visualized before implementation of a city policy, and optimal city management, consensus building, and risk reduction measures can be planned. Specifically, the system executes a series of processes as an integrated workflow. The system operates a complex architecture combining a natural language processing model, a graph neural network, and a reinforcement learning agent. The system receives spatial coordinate data of a bicycle-dedicated road, a width, and a time-series tensor of traffic volume history as input data. The system normalizes these data and constructs a multidimensional feature matrix. The system inputs the feature matrix to the complex architecture. The system outputs a congestion degree prediction score in each road segment. The system simultaneously outputs a sales fluctuation prediction value of surrounding stores as a floating-point number. The system executes an optimal detour proposal and an automatic generation process of a signal control parameter based on the output prediction score. The system includes an interface for transmitting the generated parameter to an external traffic control system. By this complex model that simultaneously calculates spatial and temporal interactions, the system accurately captures a non-linear ripple effect that a single policy exerts on the entire city. Thereby, the system exhibits a technical effect of being able to derive a global optimal solution for the entire city without falling into local optimization. This technology provides an innovative solution in specific application fields such as formulation of an optimal city infrastructure investment plan for achieving both environmental load reduction and economic revitalization, and design of a next-generation traffic network anticipating spread of autonomous driving vehicles.

The specific processing unit 290 sends the results of specific processing obtained in Example 1 or Application Example 1 described above to the smart device 14. In the smart device 14, the control unit 46A causes the output device 40 to output the results of specific processing. The microphone 38B acquires voice indicating user input in response to the results of specific processing. The control unit 46A sends the voice data indicating user input acquired by the microphone 38B to the data processing device 12. In the data processing device 12, the specific processing unit 290 acquires the voice data.

The data generation model 58 is a so-called generative AI (Artificial Intelligence).

An example of the data generation model 58 is a generative AI such as ChatGPT (registered trademark) (Internet search <URL: https://openai.com/blog/chatgpt>).

The data generation model 58 is obtained by performing deep learning on a neural network. The data generation model 58 receives prompts containing instructions and inference data such as voice data indicating voice, text data indicating text, and image data indicating images (e.g., still image data or video data). The data generation model 58 performs inference according to the instructions indicated by the prompt on the input inference data and outputs the inference results in one or more data formats such as voice data, text data, or image data. The data generation model 58 includes, for example, text generation AI, image generation AI, and multimodal generation AI. Here, inference refers to, for example, analysis, classification, prediction, and/or summarization. The specific processing unit 290 performs the specific processing described above using the data generation model 58. The data generation model 58 may be a fine-tuned model that outputs inference results from prompts without instructions, and in this case, the data generation model 58 can output inference results from prompts without instructions. The data processing device 12 and the like may include multiple types of data generation models 58, and the data generation model 58 may include AI other than generative AI. AI other than generative AI may include, for example, linear regression, logistic regression, decision trees, random forests, support vector machines (SVM), k-means clustering, convolutional neural networks (CNN), recurrent neural networks (RNN), generative adversarial networks (GAN), or naive Bayes, among others, and can perform various processing but are not limited to such examples. Additionally, AI may be an AI agent. Furthermore, when processing is performed by AI in each part described above, the processing may be performed partially or entirely by AI but is not limited to such examples. Additionally, processing implemented by AI including generative AI may be replaced with rule-based processing, and rule-based processing may be replaced with processing implemented by AI including generative AI.

Moreover, the processing by the data processing system 10 described above is executed by the specific processing unit 290 of the data processing device 12 or the control unit 46A of the smart device 14, but it may be executed by both the specific processing unit 290 of the data processing device 12 and the control unit 46A of the smart device 14. Additionally, the specific processing unit 290 of the data processing device 12 acquires or collects necessary information for processing from the smart device 14 or external devices, and the smart device 14 acquires or collects necessary information for processing from the data processing device 12 or external devices.

In the above embodiments, an example form where specific processing is performed by the data processing device 12 was described, but the technology disclosed herein is not limited to this, and specific processing may be performed by the smart device 14.

### Second Embodiment

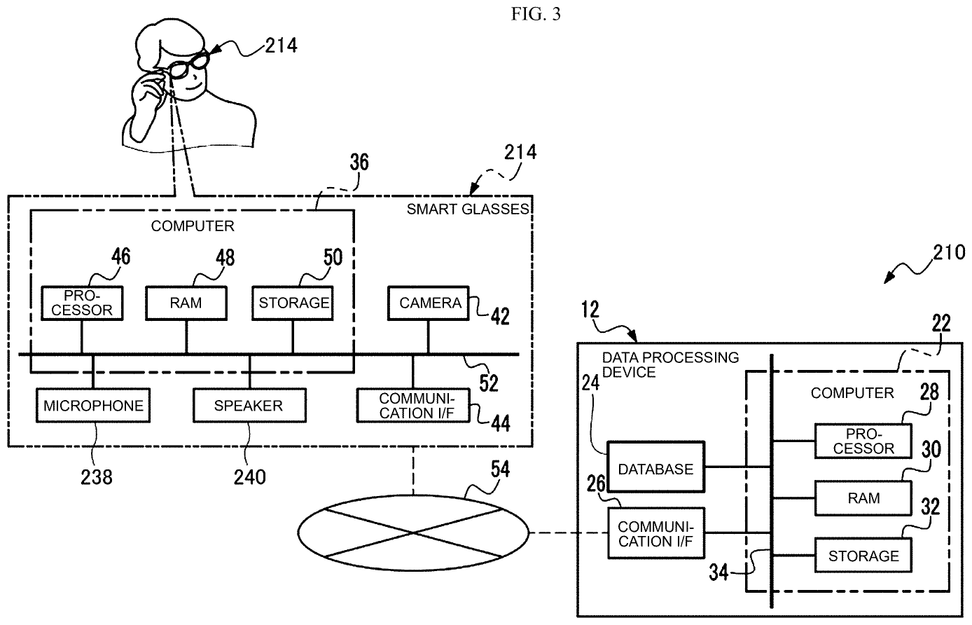

FIG. 3 shows an example configuration of a data processing system 210 according to the second embodiment.

As shown in FIG. 3, the data processing system 210 comprises a data processing device 12 and smart glasses 214. An example of the data processing device 12 is a server.

The data processing device 12 comprises a computer 22, a database 24, and a communication I/F 26. The computer 22 is an example of a “computer” related to the technology disclosed herein. The computer 22 comprises a processor 28, RAM 30, and storage 32. The processor 28, RAM 30, and storage 32 are connected to a bus 34. Additionally, the database 24 and communication I/F 26 are also connected to the bus 34. The communication I/F 26 is connected to a network 54. Examples of the network 54 include a WAN (Wide Area Network) and/or a LAN (Local Area Network), among others.

The smart glasses 214 comprise a computer 36, a microphone 238, a speaker 240, a camera 42, and a communication I/F 44. The computer 36 comprises a processor 46, RAM 48, and storage 50. The processor 46, RAM 48, and storage 50 are connected to a bus 52. The microphone 238, speaker 240, camera 42, and communication I/F 44 are also connected to the bus 52.

The microphone 238 accepts voice uttered by the user 20, accepting instructions, among others, from the user 20. The microphone 238 captures the voice emitted by the user 20, converts the captured voice into voice data, and outputs it to the processor 46. The speaker 240 outputs sound according to instructions from the processor 46.

The camera 42 is a small digital camera equipped with optical systems such as lenses, apertures, and shutters, as well as imaging elements such as CMOS (Complementary Metal-Oxide-Semiconductor) image sensors or CCD (Charge Coupled Device) image sensors, and captures the surroundings of the user 20 (e.g., an imaging range defined by an angle of view equivalent to the typical field of view of a healthy person).

The communication I/F 44 is connected to the network 54. The communication I/F 44 and 26 manage the exchange of various information between the processor 46 and the processor 28 via the network 54. The exchange of various information between the processor 46 and the processor 28 using the communication I/F 44 and 26 is conducted securely.

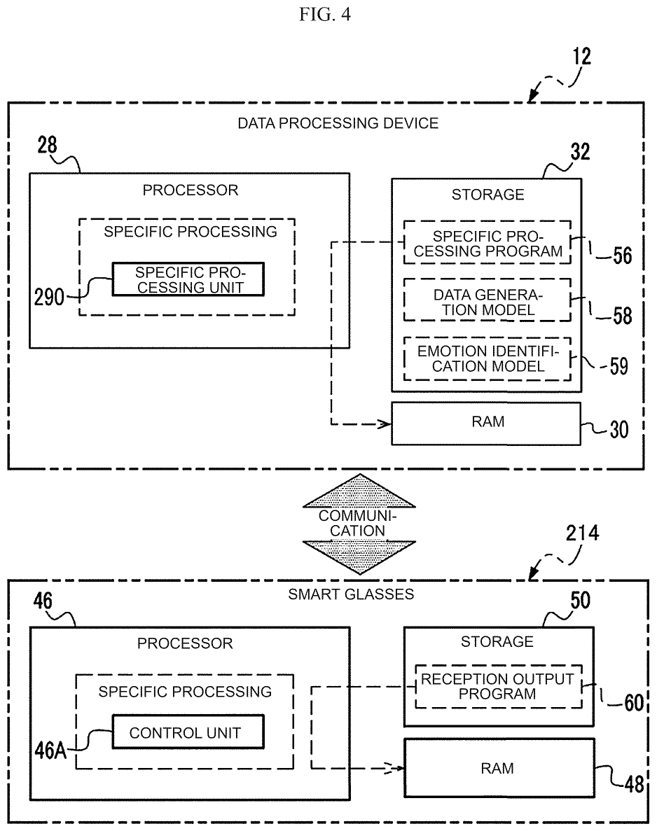

FIG. 4 shows an example of the main functions of the data processing device 12 and smart glasses 214. As shown in FIG. 4, specific processing is performed in the data processing device 12 by the processor 28. The storage 32 stores a specific processing program 56.

The specific processing program 56 is an example of a “program” related to the technology disclosed herein. The processor 28 reads the specific processing program 56 from the storage 32 and executes it on the RAM 30. The specific processing is realized by the processor 28 operating as a specific processing unit 290 according to the specific processing program 56 executed on the RAM 30.

The storage 32 stores a data generation model 58 and an emotion identification model 59. The data generation model 58 and emotion identification model 59 are used by the specific processing unit 290. The specific processing unit 290 can estimate the user's emotions using the emotion identification model 59 and perform specific processing using the user's emotions. The emotion estimation function (emotion identification function) using the emotion identification model 59 includes estimating and predicting the user's emotions, and various estimations and predictions related to the user's emotions are performed, but it is not limited to such examples. Furthermore, emotion estimation and prediction may include, for example, emotion analysis.

In the smart glasses 214, reception output processing is performed by the processor 46. The storage 50 stores a reception output program 60. The processor 46 reads the reception output program 60 from the storage 50 and executes it on the RAM 48. The reception output processing is realized by the processor 46 operating as a control unit 46A according to the reception output program 60 executed on the RAM 48. The smart glasses 214 may also have similar data generation models and emotion identification models as the data generation model 58 and emotion identification model 59, and perform the same processing as the specific processing unit 290 using these models.

Next, specific processing by the specific processing unit 290 of the data processing device 12 will be described. Each part of the system described below is realized by the data processing device 12 and the smart glasses 214. In the following description, the data processing device 12 is referred to as a “server,” and the smart glasses 214 are referred to as a “terminal.”

### Example 1

Since the flow of the specific processing is the same as that in Example 1 described in the first embodiment, the description thereof is omitted.

(Application Example 1) Since the flow of the specific processing is the same as that in Application Example 1 described in the first embodiment, the description thereof is omitted.

The specific processing unit 290 sends the results of specific processing obtained in Example 1 or Application Example 1 described above to the smart glasses 214. In the smart glasses 214, the control unit 46A causes the speaker 240 to output the results of specific processing. The microphone 238 acquires voice indicating user input in response to the results of specific processing. The control unit 46A sends the voice data indicating user input acquired by the microphone 238 to the data processing device 12. In the data processing device 12, the specific processing unit 290 acquires the voice data.

Moreover, the processing by the data processing system 10 described above is executed by the specific processing unit 290 of the data processing device 12 or the control unit 46A of the smart glasses 214, but it may be executed by both the specific processing unit 290 of the data processing device 12 and the control unit 46A of the smart glasses 214. Additionally, the specific processing unit 290 of the data processing device 12 acquires or collects necessary information for processing from the smart glasses 214 or external devices, and the smart glasses 214 acquires or collects necessary information for processing from the data processing device 12 or external devices.

In the above embodiments, an example form where specific processing is performed by the data processing device 12 was described, but the technology disclosed herein is not limited to this, and specific processing may be performed by the smart glasses 214.

### Third Embodiment

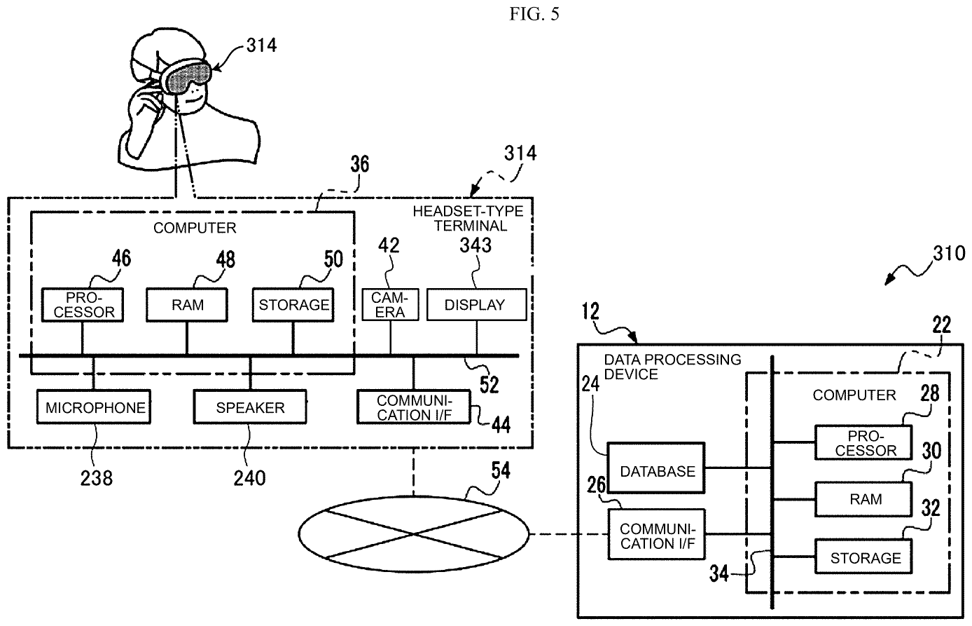

FIG. 5 shows an example configuration of a data processing system 310 according to the third embodiment.

As shown in FIG. 5, the data processing system 310 comprises a data processing device 12 and a headset-type terminal 314. An example of the data processing device 12 is a server.

The data processing device 12 comprises a computer 22, a database 24, and a communication I/F 26. The computer 22 is an example of a “computer” related to the technology disclosed herein. The computer 22 comprises a processor 28, RAM 30, and storage 32. The processor 28, RAM 30, and storage 32 are connected to a bus 34. Additionally, the database 24 and communication I/F 26 are also connected to the bus 34. The communication I/F 26 is connected to a network 54. Examples of the network 54 include a WAN (Wide Area Network) and/or a LAN (Local Area Network), among others.

The headset-type terminal 314 comprises a computer 36, a microphone 238, a speaker 240, a camera 42, a communication I/F 44, and a display 343. The computer 36 comprises a processor 46, RAM 48, and storage 50. The processor 46, RAM 48, and storage 50 are connected to a bus 52. The microphone 238, speaker 240, camera 42, display 343, and communication I/F 44 are also connected to the bus 52.

The microphone 238 accepts voice uttered by the user 20, accepting instructions, among others, from the user 20. The microphone 238 captures the voice emitted by the user 20, converts the captured voice into voice data, and outputs it to the processor 46. The speaker 240 outputs sound according to instructions from the processor 46.

The camera 42 is a small digital camera equipped with optical systems such as lenses, apertures, and shutters, as well as imaging elements such as CMOS (Complementary Metal-Oxide-Semiconductor) image sensors or CCD (Charge Coupled Device) image sensors, and captures the surroundings of the user 20 (e.g., an imaging range defined by an angle of view equivalent to the typical field of view of a healthy person).

The communication I/F 44 is connected to the network 54. The communication I/F 44 and 26 manage the exchange of various information between the processor 46 and the processor 28 via the network 54. The exchange of various information between the processor 46 and the processor 28 using the communication I/F 44 and 26 is conducted securely.

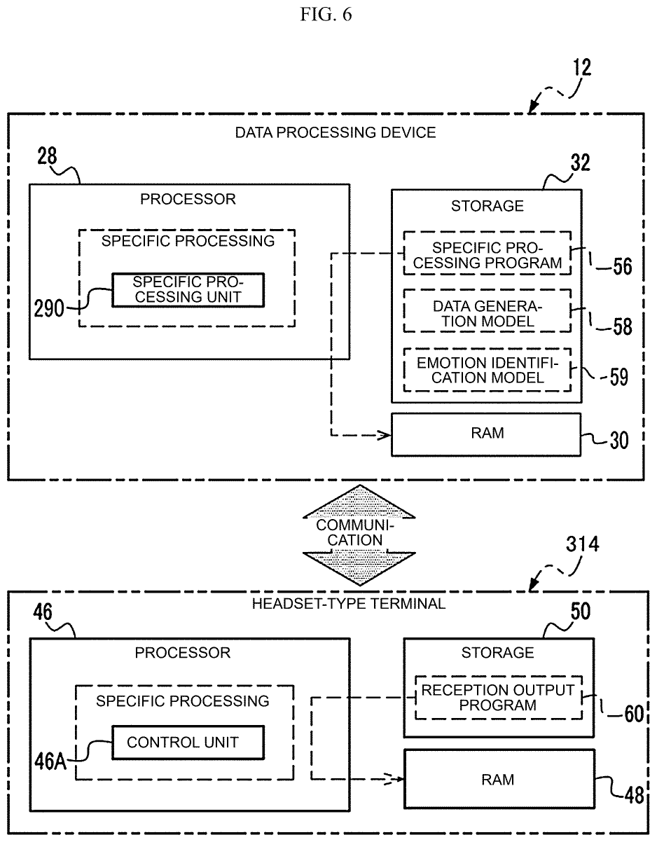

FIG. 6 shows an example of the main functions of the data processing device 12 and the headset-type terminal 314. As shown in FIG. 6, specific processing is performed in the data processing device 12 by the processor 28. The storage 32 stores a specific processing program 56.

The specific processing program 56 is an example of a “program” related to the technology disclosed herein. The processor 28 reads the specific processing program 56 from the storage 32 and executes it on the RAM 30. The specific processing is realized by the processor 28 operating as a specific processing unit 290 according to the specific processing program 56 executed on the RAM 30.

The storage 32 stores a data generation model 58 and an emotion identification model 59. The data generation model 58 and emotion identification model 59 are used by the specific processing unit 290.

In the headset-type terminal 314, reception output processing is performed by the processor 46.

The storage 50 stores a reception output program 60. The processor 46 reads the reception output program 60 from the storage 50 and executes it on the RAM 48. The reception output processing is realized by the processor 46 operating as a control unit 46A according to the reception output program 60 executed on the RAM 48.

Next, specific processing by the specific processing unit 290 of the data processing device 12 will be described. Each part of the system described below is realized by the data processing device 12 and the headset-type terminal 314. In the following description, the data processing device 12 is referred to as a “server,” and the headset-type terminal 314 is referred to as a “terminal.”

(Example 1) Since the flow of the specific processing is the same as that in Example 1 described in the first embodiment, the description thereof is omitted.

(Application Example 1) Since the flow of the specific processing is the same as that in Application Example 1 described in the first embodiment, the description thereof is omitted.

The specific processing unit 290 sends the results of specific processing obtained in Example 1 or Application Example 1 described above to the headset-type terminal 314. In the headset-type terminal 314, the control unit 46A causes the speaker 240 and the display 343 to output the results of specific processing. The microphone 238 acquires voice indicating user input in response to the results of specific processing. The control unit 46A sends the voice data indicating user input acquired by the microphone 238 to the data processing device 12. In the data processing device 12, the specific processing unit 290 acquires the voice data.

Moreover, the processing by the data processing system 10 described above is executed by the specific processing unit 290 of the data processing device 12 or the control unit 46A of the headset-type terminal 314, but it may be executed by both the specific processing unit 290 of the data processing device 12 and the control unit 46A of the headset-type terminal 314. Additionally, the specific processing unit 290 of the data processing device 12 acquires or collects necessary information for processing from the headset-type terminal 314 or external devices, and the headset-type terminal 314 acquires or collects necessary information for processing from the data processing device 12 or external devices.

In the above embodiments, an example form where specific processing is performed by the data processing device 12 was described, but the technology disclosed herein is not limited to this, and specific processing may be performed by the headset-type terminal 314.

### Fourth Embodiment

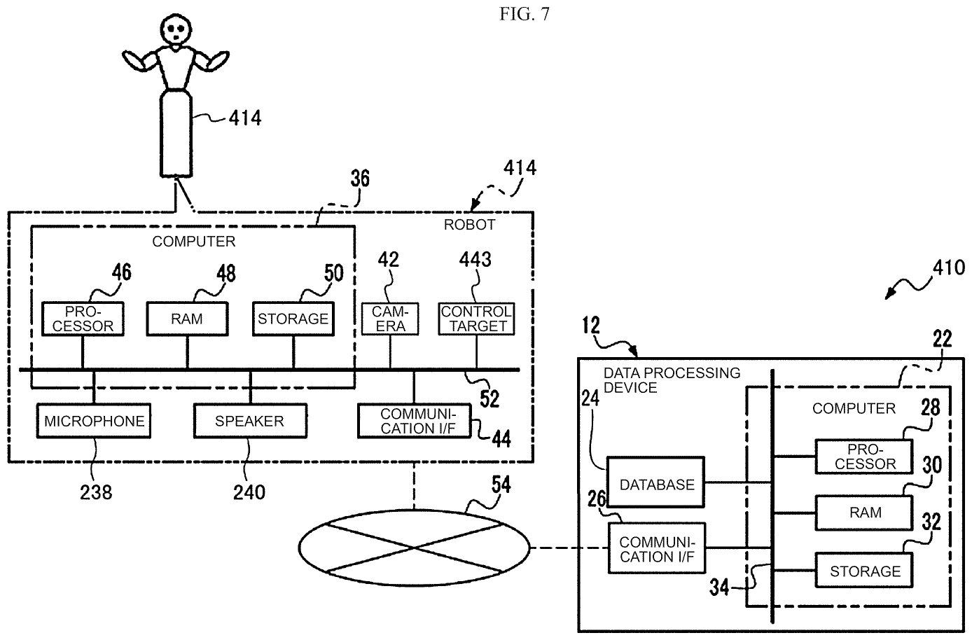

FIG. 7 shows an example configuration of a data processing system 410 according to the fourth embodiment.

As shown in FIG. 7, the data processing system 410 comprises a data processing device 12 and a robot 414. An example of the data processing device 12 is a server.

The data processing device 12 comprises a computer 22, a database 24, and a communication I/F 26. The computer 22 is an example of a “computer” related to the technology disclosed herein. The computer 22 comprises a processor 28, RAM 30, and storage 32. The processor 28, RAM 30, and storage 32 are connected to a bus 34. Additionally, the database 24 and communication I/F 26 are also connected to the bus 34. The communication I/F 26 is connected to a network 54. Examples of the network 54 include a WAN (Wide Area Network) and/or a LAN (Local Area Network), among others.

The robot 414 comprises a computer 36, a microphone 238, a speaker 240, a camera 42, a communication I/F 44, and a control target 443. The computer 36 comprises a processor 46, RAM 48, and storage 50. The processor 46, RAM 48, and storage 50 are connected to a bus 52. The microphone 238, speaker 240, camera 42, control target 443, and communication I/F 44 are also connected to the bus 52.

The microphone 238 accepts voice uttered by the user 20, accepting instructions, among others, from the user 20. The microphone 238 captures the voice emitted by the user 20, converts the captured voice into voice data, and outputs it to the processor 46. The speaker 240 outputs sound according to instructions from the processor 46.

The camera 42 is a small digital camera equipped with optical systems such as lenses, apertures, and shutters, as well as imaging elements such as CMOS (Complementary Metal-Oxide-Semiconductor) image sensors or CCD (Charge Coupled Device) image sensors, and captures the surroundings of the user 20 (e.g., an imaging range defined by an angle of view equivalent to the typical field of view of a healthy person).

The communication I/F 44 is connected to the network 54. The communication I/F 44 and 26 manage the exchange of various information between the processor 46 and the processor 28 via the network 54. The exchange of various information between the processor 46 and the processor 28 using the communication I/F 44 and 26 is conducted securely.

The control target 443 includes a display device, LEDs for the eyes, and motors for driving arms, hands, and feet, among others. The posture and gestures of the robot 414 are controlled by controlling the motors for the arms, hands, and feet, among others. Some emotions of the robot 414 can be expressed by controlling these motors. Additionally, the expression of the robot 414 can be expressed by controlling the lighting state of the LEDs for the eyes of the robot 414.

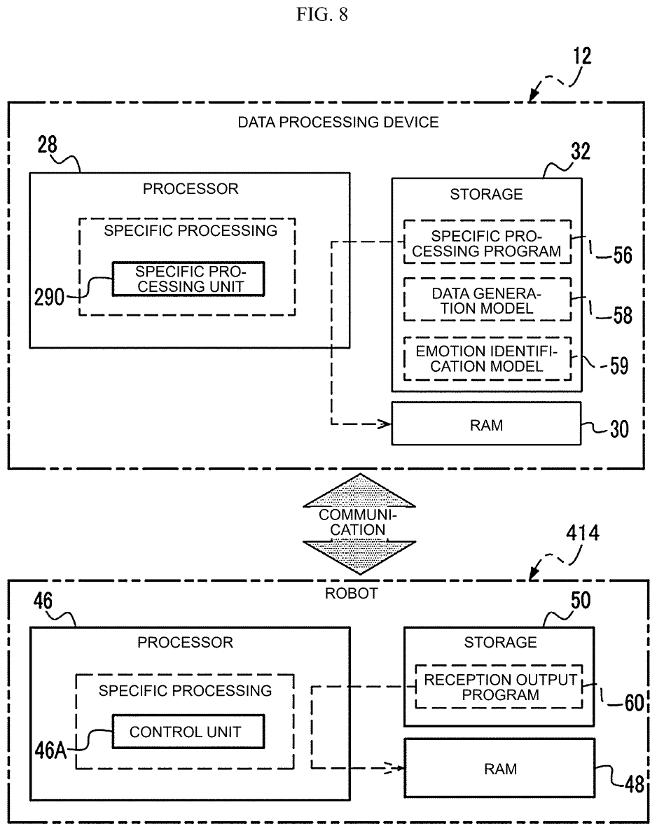

FIG. 8 shows an example of the main functions of the data processing device 12 and the robot 414. As shown in FIG. 8, specific processing is performed in the data processing device 12 by the processor 28. The storage 32 stores a specific processing program 56.

The specific processing program 56 is an example of a “program” related to the technology disclosed herein. The processor 28 reads the specific processing program 56 from the storage 32 and executes it on the RAM 30. The specific processing is realized by the processor 28 operating as a specific processing unit 290 according to the specific processing program 56 executed on the RAM 30.

The storage 32 stores a data generation model 58 and an emotion identification model 59. The data generation model 58 and emotion identification model 59 are used by the specific processing unit 290.

In the robot 414, reception output processing is performed by the processor 46. The storage 50 stores a reception output program 60. The processor 46 reads the reception output program 60 from the storage 50 and executes it on the RAM 48. The reception output processing is realized by the processor 46 operating as a control unit 46A according to the reception output program 60 executed on the RAM 48.

Next, specific processing by the specific processing unit 290 of the data processing device 12 will be described. Each part of the system described below is realized by the data processing device 12 and the robot 414. In the following description, the data processing device 12 is referred to as a “server,” and the robot 414 is referred to as a “terminal.”

(Example 1) Since the flow of the specific processing is the same as that in Example 1 described in the first embodiment, the description thereof is omitted.

(Application Example 1) Since the flow of the specific processing is the same as that in Application Example 1 described in the first embodiment, the description thereof is omitted.

The specific processing unit 290 sends the results of specific processing obtained in Example 1 or Application Example 1 described above to the robot 414. In the robot 414, the control unit 46A causes the speaker 240 and the control target 443 to output the results of specific processing. The microphone 238 acquires voice indicating user input in response to the results of specific processing. The control unit 46A sends the voice data indicating user input acquired by the microphone 238 to the data processing device 12. In the data processing device 12, the specific processing unit 290 acquires the voice data.

Moreover, the processing by the data processing system 10 described above is executed by the specific processing unit 290 of the data processing device 12 or the control unit 46A of the robot 414, but it may be executed by both the specific processing unit 290 of the data processing device 12 and the control unit 46A of the robot 414. Additionally, the specific processing unit 290 of the data processing device 12 acquires or collects necessary information for processing from the robot 414 or external devices, and the robot 414 acquires or collects necessary information for processing from the data processing device 12 or external devices.

In the above embodiments, an example form where specific processing is performed by the data processing device 12 was described, but the technology disclosed herein is not limited to this, and specific processing may be performed by the robot 414.

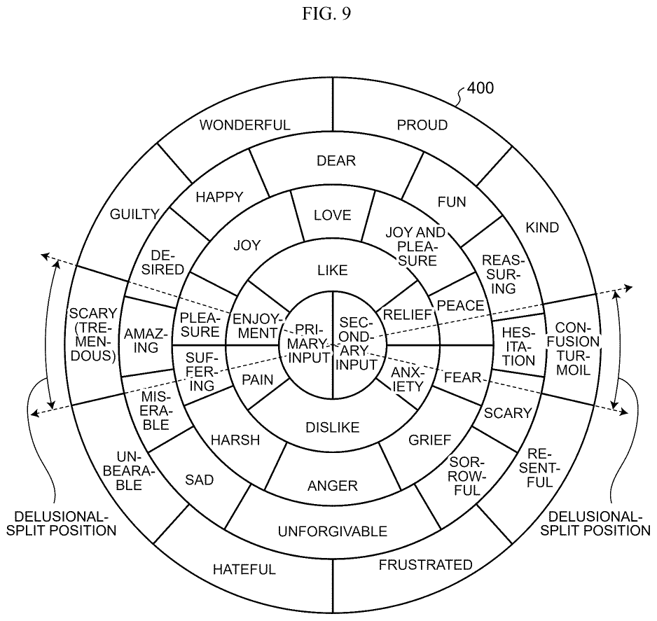

Note that the emotion identification model 59 as an emotion engine may determine the user's emotions according to a specific mapping. Specifically, the emotion identification model 59 may determine the user's emotions according to an emotion map, which is a specific mapping (see FIG. 9). Similarly, the emotion identification model 59 may determine the robot's emotions, and the specific processing unit 290 may perform specific processing using the robot's emotions.

FIG. 9 is a diagram showing an emotion map 400 where multiple emotions are mapped. In the emotion map 400, emotions are arranged concentrically radiating from the center. The closer to the center of the concentric circles, the more primitive the state of emotions is arranged. On the outer side of the concentric circles, emotions representing states and behaviors arising from mood are arranged. Emotions encompass concepts including emotional and mental states. On the left side of the concentric circles, emotions generally generated from reactions occurring in the brain are arranged. On the right side of the concentric circles, emotions generally induced by situational judgment are arranged. On the top and bottom of the concentric circles, emotions generated from reactions occurring in the brain and induced by situational judgment are arranged. Additionally, on the upper side of the concentric circles, “pleasant” emotions are arranged, and on the lower side, “unpleasant” emotions are arranged. In this way, in the emotion map 400, multiple emotions are mapped based on the structure from which emotions arise, and emotions that tend to occur simultaneously are mapped nearby.

These emotions are distributed in the 3 o'clock direction of the emotion map 400, and they usually move back and forth around reassurance and anxiety. In the right half of the emotion map 400, situational recognition takes precedence over internal sensations, giving a calm impression.

The inner side of the emotion map 400 represents the mind, and the outer side represents behavior, so the further out on the emotion map 400, the more visible (expressed in behavior) emotions become.

Here, human emotions are based on various balances like posture and blood sugar levels, and when these balances move away from the ideal, they indicate discomfort, and when they approach the ideal, they indicate comfort. In robots, cars, motorcycles, etc., emotions can be created based on various balances like posture and battery level, indicating discomfort when these balances move away from the ideal and comfort when they approach the ideal. The emotion map may be generated based on Dr. Mitsuyoshi's emotion map (Research on speech emotion recognition and brain physiological signal analysis systems related to emotions, Tokushima University, Doctoral dissertation: https://ci.nii.ac.jp/naid/500000375379). In the left half of the emotion map, emotions belonging to the domain called “reactions,” where sensations take precedence, are aligned. Additionally, in the right half of the emotion map, emotions belonging to the domain called “situations,” where situational recognition takes precedence, are aligned.

In the emotion map, two emotions that promote learning are defined. One is a negative emotion around “repentance” or “reflection” on the situation side. In other words, when a negative emotion arises in the robot, like “I never want to feel this way again” or “I don't want to be scolded again.” The other is an emotion around “desire” on the reaction side, which is positive. In other words, it is a positive feeling like “I want more” or “I want to know more.”

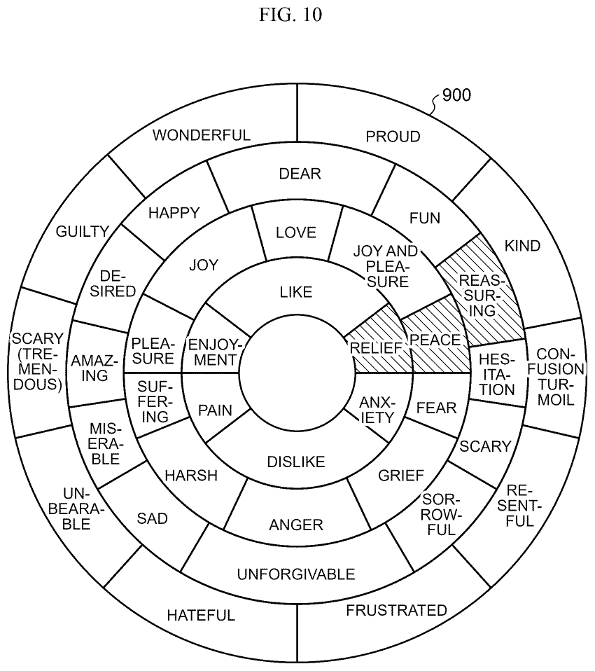

The emotion identification model 59 inputs user input into a pre-learned neural network, acquires emotion values indicating each emotion shown in the emotion map 400, and determines the user's emotions. This neural network is pre-learned based on multiple training data consisting of user input and combinations of emotion values indicating each emotion shown in the emotion map 400. Additionally, this neural network is learned so that emotions placed near each other in the emotion map 900 shown in FIG. 10 have similar values. FIG. 10 shows an example where multiple emotions like “reassured,” “calm,” and “confident” have similar emotion values.

In the above, the system according to the present disclosure has been described mainly on the functions of the data processing device 12, but the system according to the present disclosure is not necessarily mounted on a server. The system according to the present disclosure may be implemented as a general information processing system. The present disclosure may be implemented, for example, as a software program running on a personal computer, or an application running on a smartphone or the like. The method according to the present disclosure may be provided to the user in the form of SaaS (Software as a Service).

In the above embodiments, an example form where specific processing is performed by a single computer 22 was described, but the technology disclosed herein is not limited to this, and distributed processing for specific processing by multiple computers including the computer 22 may be performed. For example, the data generation model 58 may be provided in an external device of the data processing device 12, and the external device may generate data corresponding to the input data.

In the above embodiments, an example form where the specific processing program 56 is stored in the storage 32 was described, but the technology disclosed herein is not limited to this. For example, the specific processing program 56 may be stored in portable non-transitory storage media readable by a computer, such as a USB (Universal Serial Bus) memory. The specific processing program 56 stored in non-transitory storage media is installed in the computer 22 of the data processing device 12. The processor 28 executes specific processing according to the specific processing program 56.

Additionally, the specific processing program 56 may be stored in a storage device, such as a server connected to the data processing device 12 via the network 54, and downloaded and installed on the computer 22 in response to requests from the data processing device 12.

Furthermore, it is not necessary to store all of the specific processing program 56 in storage devices such as servers connected to the data processing device 12 via the network 54 or all in the storage 32, and a part of the specific processing program 56 may be stored.

Various processors, as shown next, can be used as hardware resources for executing specific processing. As processors, general-purpose processors that function as hardware resources for executing specific processing by executing software, i.e., programs, such as a CPU, can be mentioned. Additionally, as processors, dedicated electrical circuits with circuit configurations specially designed to execute specific processing, such as FPGA (Field-Programmable Gate Array), PLD (Programmable Logic Device), or ASIC (Application Specific Integrated Circuit), can be mentioned.

Each processor has a built-in or connected memory, and each processor executes specific processing using the memory.

Hardware resources for executing specific processing may be composed of one of these various processors or a combination of two or more processors of the same or different types (e.g., a combination of multiple FPGAs or a combination of a CPU and FPGA). Additionally, hardware resources for executing specific processing may be a single processor.

As an example of composing with a single processor, firstly, there is a form where one or more CPUs and software are combined to constitute a single processor, which functions as hardware resources for executing specific processing. Secondly, there is a form using a processor, such as SoC (System-on-a-chip), that realizes the function of an entire system including multiple hardware resources for executing specific processing with a single IC chip. In this way, specific processing is realized using one or more of the various processors as hardware resources.

Furthermore, as a hardware structure of these various processors, more specifically, electrical circuits combined with circuit elements such as semiconductor elements can be used. Additionally, the specific processing described above is merely one example. Therefore, it goes without saying that unnecessary steps may be deleted, new steps may be added, or the order of processing may be changed within the scope not departing from the gist.

The descriptions and drawings shown above are detailed explanations of parts related to the technology disclosed herein and are merely examples of the technology disclosed herein. For example, the explanations regarding configurations, functions, actions, and effects above are explanations regarding examples of configurations, functions, actions, and effects of parts related to the technology disclosed herein. Therefore, it goes without saying that within the scope not departing from the gist of the technology disclosed herein, unnecessary parts may be deleted, new elements may be added, or replacements may be made to the descriptions and drawings shown above. Additionally, to avoid complexity and facilitate understanding of parts related to the technology disclosed herein, explanations concerning technical common knowledge and the like that do not require special explanation for enabling the implementation of the technology disclosed herein are omitted in the descriptions and drawings shown above.

All documents, patent applications, and technical standards described in this specification are incorporated by reference to the same extent as if each document, patent application, and technical standard were specifically and individually stated to be incorporated by reference in this specification.

Note that the following supplementary notes are further disclosed regarding the above description.

### Supplementary Note 1

A system for simulating reactions and behaviors of various members in city management, comprising: an agent generation unit configured to generate and hold virtual agent data including attribute information such as role, age, gender, place of residence, health condition, commuting means, family structure, environmental awareness, motivation, satisfaction level, and past behavior history for each city member; a data analysis unit configured to collect and analyze various city data such as various sensor data, administrative records, SNS postings, questionnaire results, traffic history, commercial activity history, and disaster response records in the city, and automatically extract and update attributes and tendencies, influence relationships, and opinion formation patterns of each agent; and a simulation execution unit configured to receive a virtual policy proposal such as a city policy, an infrastructure policy, a traffic regulation, a disaster countermeasure, and an event holding as an input, simulate what kind of reaction (active approval, approval, neutrality, opposition, strong opposition, defection, proposal, etc.) or behavior (movement, participation, withdrawal, information diffusion, etc.) each agent shows to the policy proposal using generative AI, and aggregate and visualize the result by role, by region, by individual, and in chronological order, wherein the simulation execution unit is capable of highly accurately and dynamically predicting the reactions and behaviors of the various members of the entire city using natural language processing by the generative AI and inference based on attribute parameters, and multilaterally visualizing an opinion distribution, a satisfaction level change, a risk, a ripple effect, a necessity of an additional policy, and the like before implementation of a policy.

### Supplementary Note 2

The system according to Supplementary Note 1, wherein the simulation execution unit has a function of generating a large number of virtual agents of external tourists, temporary stayers, support personnel at the time of a disaster, event participants, and the like in addition to the city members, assigning various parameters such as age, gender, place of origin, purpose of stay, moving means, health condition, information sensitivity, and past city use tendency to each agent, simulating how a specific city policy or event affects an inflow from outside the city or a social ripple, or how an evacuation behavior or information propagation at the time of a disaster occurs using the generative AI, and visualizing the result in chronological order.

### Supplementary Note 3

The system according to Supplementary Note 1, wherein the data analysis unit automatically collects and analyzes sensor data, SNS postings, traffic history, commercial activity history, administrative records, questionnaire results, and the like inside and outside the city, continuously learns and updates a psychological tendency, an opinion formation pattern, an influence relationship, a satisfaction level fluctuation factor, an information diffusion tendency, and the like of each agent using the generative AI, and realizes highly accurate reaction and behavior prediction reflecting the latest city state and social trend at the time of simulation execution.

What is claimed is:

1. A system comprising:
circuitry configured to:
receive, via a communication interface coupled to a packet-switched network, historical interaction record data and behavioral tendency data from a plurality of data source systems, and store the received data in a storage device;
apply a data analysis model to the historical interaction record data and the behavioral tendency data to extract attribute feature vectors and behavioral tendency parameters for each entity identifier, and update stored agent data records with the extracted attribute feature vectors and behavioral tendency parameters;
instantiate a plurality of agent objects in a virtual simulation environment on a memory of a cloud computing node, each agent object initialized with attribute feature vectors and behavioral tendency parameters from a corresponding agent data record, and execute simulations in the virtual simulation environment at large scale utilizing tensor processing cores;
receive simulation scenario data from a terminal device via the communication interface, apply a generative neural network model to each instantiated agent object and the simulation scenario data to generate agent response prediction data comprising a response category distribution and a reasoning text for each agent identifier; and
aggregate the agent response prediction data across all agent identifiers and transmit aggregated simulation output data and visualization data to terminal devices via the communication interface.

2. The system according to claim 1, wherein the circuitry is configured to apply a distributed data processing framework to process petabyte-scale historical interaction record data in parallel across a plurality of computing nodes, and apply a natural language processing model to text data within the historical interaction record data to extract named entity labels, sentiment indicators, and topic category features as components of the behavioral tendency parameters.

3. The system according to claim 2, wherein the circuitry is configured to apply positional encoding to sequential interaction record token sequences prior to processing by the natural language processing model, compute attention-weighted representations of sequential interaction patterns, and derive temporal trend vectors representing changes in behavioral tendency parameters over configurable time windows.

4. The system according to claim 1, wherein the circuitry is configured to instantiate agent objects on a scale of millions by applying a memory-efficient agent representation that encodes attribute feature vectors as compact fixed-dimension numerical arrays, allocate agent object arrays in GPU memory for parallel processing, and execute agent response prediction inference in batches utilizing tensor core acceleration.

5. The system according to claim 4, wherein the circuitry is configured to apply the generative neural network model to each agent object by conditioning response prediction on the agent's attribute feature vector and behavioral tendency parameters alongside the simulation scenario embedding, and generating the response category distribution as a probability vector over a set of response category labels using a softmax output layer.

6. The system according to claim 1, wherein the circuitry is configured to apply a graph neural network to a relational graph of agent identifiers with edges representing interaction history links between agent pairs, execute message passing operations to propagate behavioral influence features between connected agent nodes, and incorporate the propagated influence features as additional inputs in the agent response prediction process.

7. The system according to claim 6, wherein the circuitry is configured to model cascade effects in simulation scenarios by iteratively re-applying the generative neural network model to agent objects whose behavioral tendency parameters are influenced by the initial response predictions of connected agent nodes, and computing updated response category distributions after each cascade iteration until a convergence criterion is satisfied.

8. The system according to claim 1, wherein the circuitry is configured to receive simulation scenario data in natural language text from the terminal device, apply the natural language processing model to extract structured scenario parameters comprising scenario type identifiers and contextual condition parameters, and generate the simulation scenario embedding from the extracted parameters for conditioning the generative neural network model.

9. The system according to claim 8, wherein the circuitry is configured to apply a scenario comparison model by executing simulation runs for a plurality of distinct simulation scenario data inputs, aggregating response category distributions for each scenario, and generating a comparative scenario analysis data record ranking simulation scenarios by aggregate response patterns.

10. The system according to claim 1, wherein the circuitry is configured to apply a Monte Carlo sampling procedure to the agent response prediction data by executing a plurality of stochastic simulation runs with varied random seed values, computing confidence intervals for each response category probability value, and incorporating the confidence intervals as uncertainty bounds in the aggregated simulation output data.

11. The system according to claim 1, wherein the circuitry is configured to generate visualization data from the aggregated simulation output data comprising response category distribution charts per agent identifier cluster, temporal response evolution plots across cascade iterations, and geographic distribution heat maps when agent identifier records include location attribute parameters.

12. The system according to claim 1, wherein the circuitry is configured to apply an AI learning management model to update the generative neural network model by generating training pairs from historical simulation scenario data records and corresponding validated observed response outcome records, and fine-tuning the model to improve response prediction accuracy for specific scenario type and agent attribute combination patterns.

13. The system according to claim 1, wherein the circuitry is configured to receive feedback data from terminal devices following simulation review comprising accuracy rating values and correction annotations, store the feedback as validated outcome records, and incorporate the validated outcome records in subsequent model fine-tuning cycles.

14. The system according to claim 1, wherein the circuitry is configured to generate a natural language interpretation report from the aggregated simulation output data by applying the generative neural network model to produce a summary describing predominant response patterns, key influential agent identifier clusters, and actionable implications of the simulation results.

15. The system according to claim 1, wherein the circuitry is configured to apply a sensitivity analysis model to the simulation by executing agent response prediction with systematically varied attribute feature vector values, computing the change in aggregate response category distribution for each varied dimension, and generating a sensitivity report identifying attribute feature dimensions with the highest influence on simulation outcomes.

16. The system according to claim 1, wherein the circuitry is configured to distribute simulation execution tasks across a plurality of cloud computing nodes via a load balancer, assign agent object batches to available GPU computing nodes, and aggregate partial simulation results from all nodes into the final aggregated simulation output data.

17. The system according to claim 1, wherein the historical interaction record data comprises organizational communication records and behavioral event data, the agent data records represent entities within an organizational system, and the simulation scenario data represents a proposed policy or operational change for which organizational response prediction is desired.

18. A system comprising:
circuitry configured to:
receive, via a communication interface coupled to a packet-switched network, historical interaction records and behavioral tendency data, and apply a distributed data processing framework to extract attribute feature vectors and behavioral tendency parameters;
instantiate millions of agent objects in a virtual simulation environment utilizing tensor processing cores, apply a generative neural network model conditioned on agent attributes and simulation scenario data to generate response category distributions;
apply a graph neural network to model cascade effects across connected agent nodes;
aggregate response prediction data and apply a Monte Carlo sampling procedure to compute confidence intervals; and
transmit aggregated simulation output data and natural language interpretation reports to terminal devices.

19. The system according to claim 18, wherein the circuitry is configured to apply a scenario comparison model to rank multiple simulation scenarios by aggregate response patterns, apply a sensitivity analysis model to identify high-influence attribute dimensions, and apply an AI learning management model to update the generative neural network model using validated observed response outcome records.

20. A method comprising:
receiving, via a communication interface coupled to a packet-switched network, historical interaction record data and behavioral tendency data, and storing in a storage device;
applying a data analysis model to extract attribute feature vectors and behavioral tendency parameters for each entity identifier;
instantiating agent objects in a virtual simulation environment utilizing tensor processing cores, and applying a generative neural network model to generate agent response prediction data;
aggregating agent response prediction data and applying Monte Carlo sampling to compute confidence intervals; and
transmitting aggregated simulation output data and visualization data to terminal devices via the communication interface.
